(19) United States
(12) Patent Application Publication
(10) Pub. No.: US 2025/0070039 A1
(43) Pub. Date: Feb. 27, 2025

(54) SEMICONDUCTOR PACKAGE AND MANUFACTURING METHOD THEREOF

(71) Applicant: SAMSUNG ELECTRONICS CO., LTD., Suwon-si (KR)

(72) Inventor: Kwangyong Lee, Suwon-si (KR)

(21) Appl. No.: 18/632,486

(22) Filed: Apr. 11, 2024

(30) Foreign Application Priority Data
Aug. 22, 2023 (KR) 10-2023-0110034

(51) Int. Cl. H01L 23/544; H01L 23/00; H01L 25/065

(52) U.S. Cl. CPC H01L 23/544; H01L 24/32; H01L 24/48; H01L 24/73; H01L 25/0657; H01L 2223/54426; H01L 2224/32145; H01L 2224/32225; H01L 2224/48227; H01L 2224/73215; H01L 2225/0651; H01L 2225/06562

(57) ABSTRACT

A semiconductor package includes a package substrate and at least two semiconductor chips stacked on the package substrate and electrically connected to the package substrate via a wire, in which a first semiconductor chip located on a lower side among the at least two semiconductor chips is coupled, without an adhesive, to a second semiconductor chip located above the first semiconductor chip.

### CROSS-REFERENCE TO RELATED APPLICATION

This application claims priority to Korean Patent Application No. 10-2023-0110034, filed in the Korean Intellectual Property Office on Aug. 22, 2023, the disclosure of which is incorporated by reference herein in its entirety.

### BACKGROUND

Electronic apparatuses are becoming more compact and lightweight according to rapid development of the electronics industry and users' demand. As the electronic apparatuses become smaller and lighter, semiconductor packages used therein are also smaller and lighter. In addition, high reliability along with high performance and large capacity are required for the semiconductor packages. In order to achieve large capacity and high performance, the thickness of semiconductor packages has been increasing and the supply power has also been increasing. However, an increase in thickness thereof makes it difficult to achieve reduction in the size and weight of the semiconductor packages, and an increase in supply power thereto may greatly affect high reliability.

### SUMMARY

In general, in some aspects, the present disclosure is directed toward a semiconductor package having minimal total thickness and a method of manufacturing a semiconductor package.

According to some aspects of the present disclosure, a semiconductor package includes a package substrate and at least two semiconductor chips stacked on the package substrate and electrically connected to the package substrate via a wire, wherein a first semiconductor chip located on a lower side among the at least two semiconductor chips is coupled, without an adhesive, to a second semiconductor chip located above the first semiconductor chip.

According to some aspects of the present disclosure, a semiconductor package includes a package substrate having a solder resist (SR) layer formed on an upper surface thereof, a first semiconductor chip coupled to the package substrate without an adhesive and electrically connected to the package substrate via a wire, and at least two second semiconductor chips coupled to the first semiconductor chip without an adhesive and electrically connected to the package substrate via a wire, wherein a lower second semiconductor chip located on a lower side among the at least two second semiconductor chips is coupled, without an adhesive, to an upper second semiconductor chip located above the lower second semiconductor chip, the lower second semiconductor chip lowermost among the at least two second semiconductor chips is self-aligned with a first alignment pattern line on an upper surface of the first semiconductor chip, and the upper second semiconductor chip is self-aligned with a second alignment pattern line on an upper surface of the lower second semiconductor chip.

According to some aspects of the present disclosure, a semiconductor package includes a package substrate and at least two semiconductor chips stacked on the package substrate and each having an upper surface and a lower surface having rectangular shapes, wherein the upper surface of each of the at least two semiconductor chips includes an active surface and the lower surface of each of the at least two semiconductor chips includes a non-active surface, and chip pads are arranged in a first direction on the upper surface of each of the at least two semiconductor chips and are adjacent to a first edge that corresponds to one line of the rectangular shapes of the upper and lower surfaces of each of the at least two semiconductor chips and extends in the first direction, the at least two semiconductor chips are stacked on each other such that the chip pads thereof are exposed to the outside, and the chip pads are electrically connected to substrate pads of the package substrate via wires, and a first semiconductor chip located on a lower side among the at least two semiconductor chips is coupled, without an adhesive, to a second semiconductor chip located above the first semiconductor chip.

According to some aspects of the present disclosure, a method of manufacturing a semiconductor package includes forming alignment pattern lines on upper surfaces of semiconductor chips, stacking a first semiconductor chip among the semiconductor chips on a package substrate, applying a hydrophilic liquid on an upper surface of the first semiconductor chip, stacking a second semiconductor chip among the semiconductor chips on the first semiconductor chip, and heat-treating the first semiconductor chip and the second semiconductor chip, wherein, during the heat-treating of the first semiconductor chip and the second semiconductor chip, the hydrophilic liquid is removed, and the first semiconductor chip and the second semiconductor chip are coupled to each other by van der Waals force without an adhesive.

### BRIEF DESCRIPTION OF THE DRAWINGS

Exemplary implementations will be more clearly understood from the following detailed description, taken in conjunction with the accompanying drawings.

FIG. 1A is a cross-sectional view of an example of a semiconductor package according to some implementations and FIG. 1B is a plan view of the semiconductor chip included in the semiconductor package of FIG. 1A according to some implementations.

FIG. 2 is a cross-sectional view of an example of a semiconductor package according to some implementations.

FIGS. 3A and 3B are plan views of an example of a semiconductor chip included in the semiconductor package of FIG. 1A according to some implementations.

FIG. 4A is a cross-sectional view of an examples of a semiconductor package according to some implementations and FIG. 4B is a plan view of the semiconductor chip included in the semiconductor package of FIG. 4A according to some implementations.

FIG. 5A is a cross-sectional view of an example of a semiconductor package according to some implementations, FIG. 5B is a plan view of an example of a semiconductor chip included in the semiconductor package of FIG. 5A according to some implementations, and FIG. 5C is an enlarged view of region A of FIG. 5A according to some implementations.

FIGS. 6A and 6B are cross-sectional views of an example of a semiconductor packages according to some implementations.

FIG. 7A is a graph showing thicknesses of die attach films (DAF) versus numbers of semiconductor chips according to some implementations, and FIG. 7B is a graph showing chip thicknesses according to various chip stack structures with respect to total heights of semiconductor packages according to some implementations.

FIG. 8A is a cross-sectional view of an example of a semiconductor package according to some implementations and FIG. 8B is a plan view of an example of a package substrate included in the semiconductor package of FIG. 8A according to some implementations.

FIGS. 9A to 13 are cross-sectional views and plan views showing an example of a process of manufacturing a semiconductor package according to some implementations.

FIGS. 14A to 16B are cross-sectional views and plan views showing an example of a process of manufacturing a semiconductor package according to some implementations.

FIGS. 17A to 19B are cross-sectional views and plan views showing an example of a process of manufacturing a semiconductor package according to some implementations.

FIGS. 20A to 22B are cross-sectional views and plan views showing an example of a process of manufacturing a semiconductor package according to some implementations.

### DETAILED DESCRIPTION

Hereinafter, exemplary implementations will be described in detail with reference to the accompanying drawings. The same reference numerals are given to the same elements in the drawings, and repeated descriptions thereof are omitted.

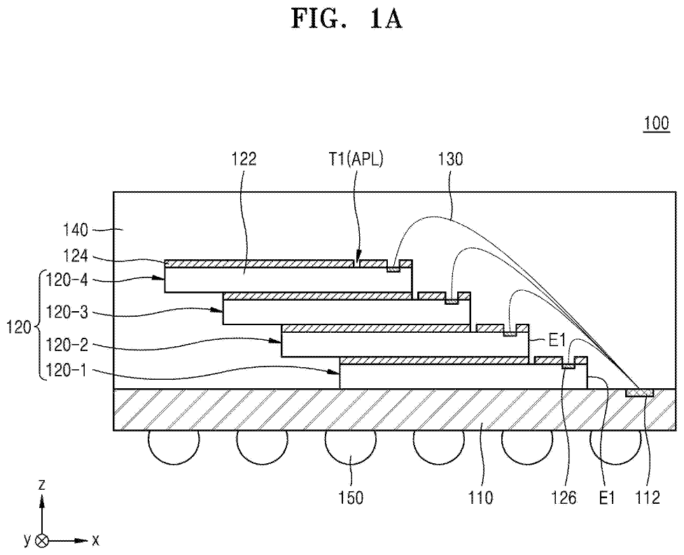

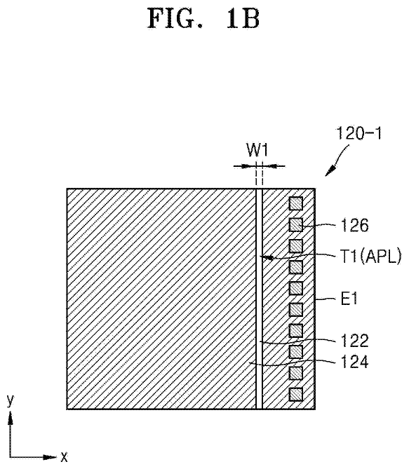

FIG. 1A is a cross-sectional view of an example of a semiconductor package 100 according to some implementations and FIG. 1B is a plan view of an example of a semiconductor chip included in the semiconductor package 100 of FIG. 1A according to some implementations. In FIGS. 1A and 1B, the semiconductor package 100 may include a package substrate 110, a chip stack structure 120, a sealing material 140, and an external connection terminal 150.

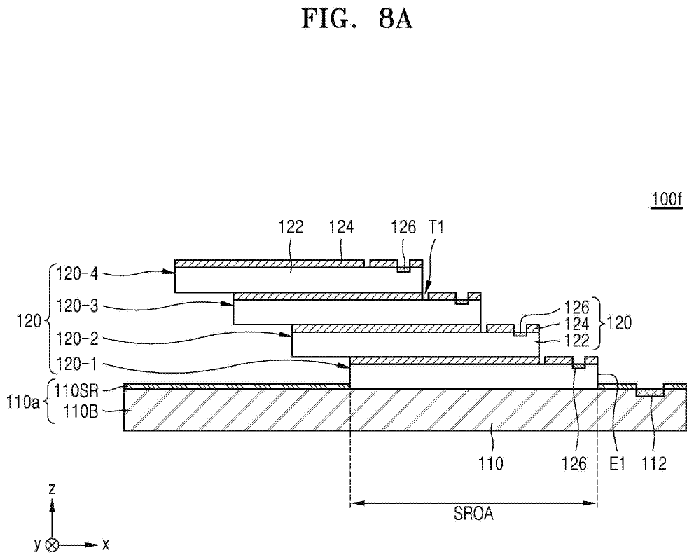

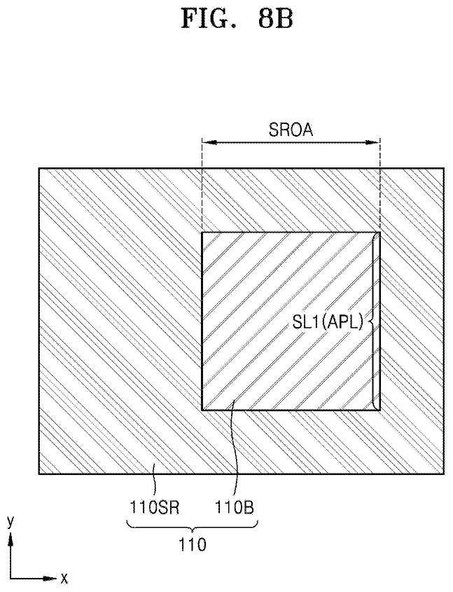

The package substrate 110 may include a substrate body layer 110B (see FIG. 8A), a substrate protective layer 110SR (see FIG. 8A), a substrate pad 112, and an external pad. The external connection terminal 150 may be disposed on the external pad. In FIG. 1A, for convenience of illustration, the substrate body layer and the substrate protective layer are not distinguished from each other, but are represented as a single layer, and the external pad is not shown.

The substrate body layer may include various materials. For example, the substrate body layer may include silicon, ceramic, an organic material, glass, epoxy resin, or the like, depending on the type of package substrates. In the semiconductor package 100, the package substrate 110 may include a printed circuit board (PCB) and the substrate body layer may be formed based on glass epoxy (or FR-4) resin, phenolic resin, or bismaleimide triazine (BT) resin. However, the material of the substrate body layer is not limited to the materials described above.

In some implementations, the substrate body layer may include a single layer or layers. For example, the package substrate 110 may include a single layer PCB having a wire formed on only one side thereof or a double layer PCB having a wire formed on two sides thereof. In the double layer PCB, the upper wire and the lower wire may be electrically connected to each other through a via contact that passes through the substrate body layer. In addition, three or more layers of copper foil (Cu foil) may be formed on the substrate body layer using an insulator including prepreg. In some implementations, three or more layers of wires may be formed on the substrate body layer depending on the number of layers of Cu foil.

Substrate protective layers may be respectively disposed on the lower surface and the upper surface of the substrate body layer. The substrate protective layers may cover and protect wires arranged on the upper surface and the lower surface of the substrate body layer. The substrate protective layer may include, for example, a solder resist (SR), particularly a photo SR (PSR). Here, the PSR may include an SR that may be patterned through an exposure process. However, in some implementations, the material of the substrate protective layer is not limited to the SR or PSR. For example, depending on the type or function of the substrate body layer, the substrate protective layer may include a passivation layer, such as an oxide film and a nitride film. Also, the substrate pad 112 on the upper surface of the substrate body layer and the external pad on the lower surface of the substrate body layer may be exposed through the substrate protective layer. In addition, the substrate body layer may occupy most of the package substrate 110 and may be substantially the same as the package substrate 110 in appearance. Accordingly, in some implementations, the substrate body layer and the package substrate 110 may be used as substantially the same concept.

The substrate pad 112 may be disposed on the upper surface of the package substrate 110 and electrically connected to a corresponding chip pad 126 of the semiconductor chip of the chip stack structure 120 through a wire 130. As shown in FIG. 1A, chip pads 126 of semiconductor chips in the chip stack structure 120 may all be connected to the substrate pad 112. Accordingly, the number of substrate pads 112 and the number of chip pads 126 of each of the semiconductor chips may be equal to each other. However, in some implementations, different substrate pads may be arranged respectively corresponding to the semiconductor chips. In some implementations, a substrate pad 112 connected to a semiconductor chip at a low position may be located close to the chip stack structure 120, and a substrate pad 112 connected to a semiconductor chip at a high position may be located far from the chip stack structure 120.

The external pad may be disposed on the lower surface of the package substrate 110. As described above, the substrate protective layer may be disposed on the lower surface of the package substrate 110, and the external pad may pass through the substrate protective layer and be exposed to the outside. The external pad may be connected to a wire inside the substrate body layer through a via contact, and the external connection terminal 150 may be disposed on the external pad.

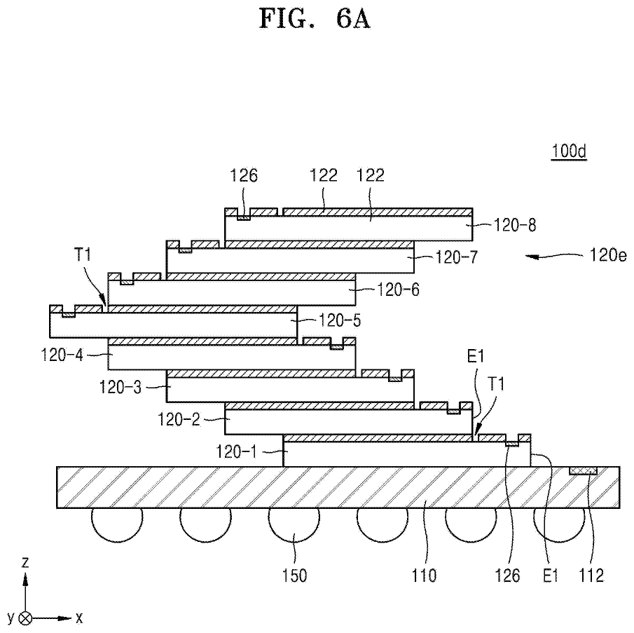

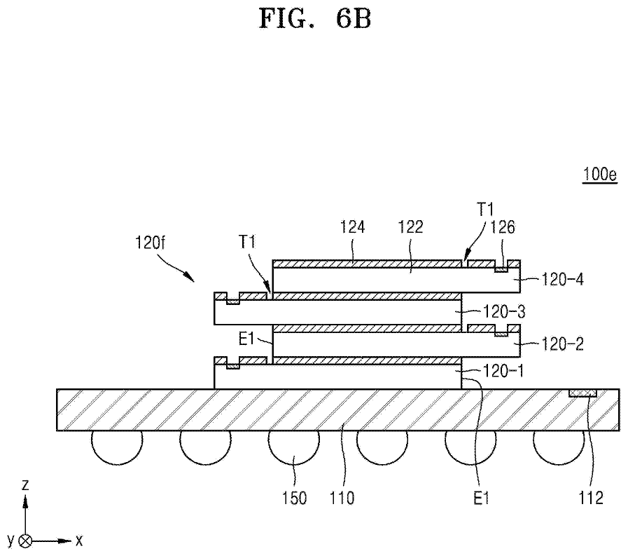

The chip stack structure 120 may be mounted on the package substrate 110 and include four semiconductor chips 120-1 to 120-4 (or referred to as first to fourth semiconductor chips 120-1 to 120-4). In the semiconductor package 100, the chip stack structure 120 includes four semiconductor chips 120-1 to 120-4, but the number of semiconductor chips in the chip stack structure 120 is not limited to four. For example, in some implementations, the chip stack structure 120 may include two, three, or five or more semiconductor chips. In some implementations, a chip stack structure may include eight semiconductor chips, as is described below with reference to FIG. 6A.

In the chip stack structure 120, the first semiconductor chip 120-1, the second semiconductor chip 120-2, the third semiconductor chip 120-3, and the fourth semiconductor chip 120-4 may be sequentially stacked in a step shape on the package substrate 110. In some implementations, the four semiconductor chips 120-1 to 120-4 may be identical to each other in terms of size and functionality. Accordingly, for simplicity, the first semiconductor chip 120-1 is described below.

The first semiconductor chip 120-1 may include a chip body layer 122, a chip protective layer 124, and a chip pad 126. The chip body layer 122 may include a semiconductor substrate, an element layer, and a multi-wiring layer. The semiconductor substrate may be based on a semiconductor material, such as a silicon wafer. The element layer may be formed on the semiconductor substrate and include various types of elements. For example, in some implementations, the element layer may include various semiconductor elements, such as field effect transistors (FET), including a planar FET or a FinFET, memory elements, including a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), and a resistive random access memory (RRAM), logic elements, including an AND, an OR, and a NOT, system large scale integration (LSI), complementary metal oxide semiconductor imaging sensors (CIS), and micro-electro-mechanical systems (MEMS). In the semiconductor package 100 according to some implementations, the first semiconductor chip 120-1 may include a DRAM chip including DRAM elements in an element layer. However, in the semiconductor package 100 according to some implementations, the type of the first semiconductor chip 120-1 is not limited to the DRAM chip.

The chip protective layer 124 may cover and protect the upper surface of the chip body layer 122. The chip protective layer 124 may include, for example, polyimide (PI). In particular, the chip protective layer 124 may include photosensitive (PS) PI, which is easy to pattern. However, the material of the chip protective layer 124 is not limited to the PI or PSPI. Also, in the semiconductor package 100 according to some implementations, the upper surface of the chip protective layer 124 may have hydrophilicity. Here, the hydrophilicity may refer to properties of easily combining with polar molecules, such as water molecules. The properties opposite to the hydrophilicity are defined as hydrophobicity, and the hydrophobicity may refer to properties of not combining with polar molecules, such as water molecules. Also, the hydrophilicity of the upper surface of the chip protective layer 124 may result from the characteristics of the material of the chip protective layer 124 or may be given by separate plasma treatment. In the semiconductor package 100 according to some implementations, the chip protective layer 124 may include, for example, the PSPI and have an upper surface imparted with the hydrophilicity through the plasma treatment.

The chip pads 126 may be arranged on the upper surface of the first semiconductor chip 120-1. Accordingly, the upper surface of the first semiconductor chip 120-1 may have an active surface and the lower surface of the first semiconductor chip 120-1 may have a non-active surface. In some implementations, the chip pads 126 may be arranged so as to be shifted to one region in an x-direction. For example, the chip pads 126 may be adjacent to a first edge E1 and arranged in a y-direction. When the upper surface or lower surface of the first semiconductor chip 120-1 has a rectangular shape, the first edge E1 may correspond to one line, which is adjacent to the chip pads 126 and extend in the y-direction. Here, the chip pads 126 may be exposed from the chip protective layer 124, and may be electrically and respectively connected to substrate pads 112 of the package substrate 110 through wires 130.

An alignment pattern line APL may be formed in the chip protective layer 124. In the semiconductor package 100 according to some implementations, the alignment pattern line APL may be formed as a first trench T1 having a line shape. For example, the first trench T1 may be adjacent to the first edge E1 of the first semiconductor chip 120-1 in the x-direction and extend in the y-direction parallel to the first edge E1. The first trench T1 may pass through (extend into) the chip protective layer 124 and expose the chip body layer 122 at the bottom surface thereof. As described above, the upper surface of the chip protective layer 124 may be hydrophilic, whereas the upper surface of the chip body layer 122 exposed in a line shape through the first trench T1 may be hydrophobic.

In some implementations, the first trench T1 may have a first width W1 in a direction perpendicular to the direction in which the first trench T1 extends. For example, the first trench T1 may extend in the y-direction and have the first width W1 in the x-direction. The first width W1 may be, for example, about 10 μm. However, the first width W1 of the first trench T1 is not limited to 10 μm.

In some implementations, the first semiconductor chip 120-1 may be directly coupled to and stacked on the upper surface of the package substrate 110. Accordingly, there may be no adhesive layer between the first semiconductor chip 120-1 and the package substrate 110. A structure in which the first semiconductor chip 120-1 is directly coupled to the upper surface of the package substrate 110 is described below in more detail with reference to FIGS. 8A and 8B.

In some implementations, the second semiconductor chip 120-2 may be directly coupled to and stacked on the first semiconductor chip 120-1 without an adhesive layer. In addition, the third semiconductor chip 120-3 may be directly coupled to and stacked on the second semiconductor chip 120-2 without an adhesive layer and the fourth semiconductor chip 120-4 may be directly coupled to and stacked on the third semiconductor chip 120-3 without an adhesive layer. Since, in some implementations, the coupling and stacking structures between the semiconductor chips are all the same, the description focuses on the coupling and stacking structure between the first semiconductor chip 120-1 and the second semiconductor chip 120-2.

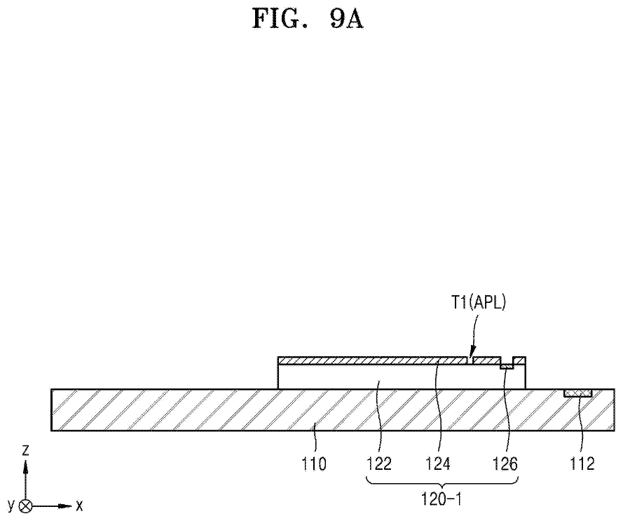

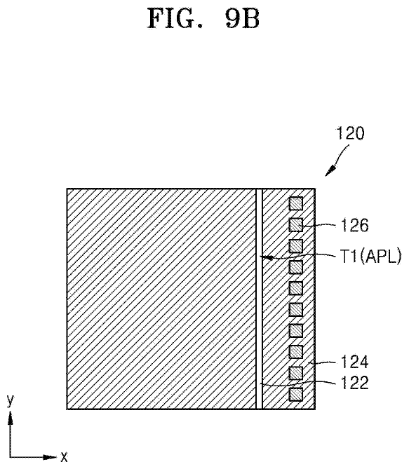

In some implementations, the second semiconductor chip 120-2 may be directly coupled to the first semiconductor chip 120-1 without an adhesive layer. For example, the second semiconductor chip 120-2 may be directly coupled to the first semiconductor chip 120-1 by van der Waals force, rather than by adhesive force from an adhesive layer. Also, the second semiconductor chip 120-2 may be self-aligned with the alignment pattern line APL of the first semiconductor chip 120-1. For example, the first edge E1 of the second semiconductor chip 120-2 may be self-aligned with the first trench T1, which is the alignment pattern line APL of the first semiconductor chip 120-1. Here, the self-alignment may represent a state in which alignment is automatically made by the structure or characteristics of the semiconductor chip itself without performing an artificial alignment process. In the semiconductor package 100, according to some implementations, the self-alignment of the second semiconductor chip 120-2 may be made due to the surface tension of the hydrophilic liquid. The self-alignment of the second semiconductor chip 120-2 is described below in more detail with reference to FIGS. 9A to 13.

The first edge E1 of the second semiconductor chip 120-2 is self-aligned with the first trench T1 of the first semiconductor chip 120-1, and other semiconductor chips are self-aligned with underlying semiconductor chips in the same structures. Accordingly, as shown in FIG. 1A, the four semiconductor chips 120-1 to 120-4 may be stacked in a step shape on the semiconductor substrate 110. Due to this step-shaped stack structure, the chip pads 126 of each of the four semiconductor chips 120-1 to 120-4 may be exposed to the outside. Accordingly, the chip pads 126 may be connected to the substrate pads 112 through the wires 130.

However, in some implementations, when semiconductor chips are stacked in a step shape in only one direction, as the number of semiconductor chips increases, the width of the semiconductor package in one direction may become excessively large. Accordingly, as the number of semiconductor chips increases, the semiconductor chips may be stacked in the form of Z-shaped steps. In some implementations, the semiconductor chips may be stacked in a zigzag shape rather than a step shape. The chip stack structure in the form of Z-shaped steps or the chip stack structure in the form of zigzag is described below in more detail with reference to FIGS. 6A and 6B.

The sealing material 140 may cover the upper and side surfaces of the chip stack structure 120 and the wire 130 above the upper surface of the package substrate 110. The sealing material 140 may have a certain thickness and cover the upper surface of the chip stack structure 120. The sealing material 140 may include a thermosetting resin, such as an epoxy resin, a thermoplastic resin, such as PI, or a resin formed by adding a reinforcing material, such as an inorganic filler, to the thermosetting resin or the thermoplastic resin, for example, ABF, FR-4, and BT. Also, the scaling material 140 may include a molding material, such as an epoxy mold compound (EMC). However, the material of the sealing material 140 is not limited to the materials described above.

In some implementations, the external connection terminal 150 may be disposed on the lower surface of the package substrate 110. For example, the external connection terminal 150 may be disposed on the external pad on the lower surface of the package substrate 110. The external connection terminal 150 may be electrically connected to a wire of the package substrate 110 through the external pad. Also, the external connection terminal 150 may include a solder ball. In some implementations, the external connection terminal 150 may include a pillar and solder. In some implementations, the semiconductor package 100 may be mounted on an external substrate, such as an interposer or base substrate, through the external connection terminal 150.

In some implementations, the semiconductor package 100 may include the chip stack structure 120 stacked on the package substrate 110, and the chip stack structure 120 may include the four semiconductor chips 120-1 to 120-4. In the chip stack structure 120, an upper semiconductor chip may be self-aligned and directly coupled to a lower semiconductor chip located below the upper semiconductor chip without an adhesive layer. For example, there is no separate adhesive layer between the upper semiconductor chip and the lower semiconductor chip, and the upper semiconductor chip and the lower semiconductor chip may be directly coupled to each other by van der Waals force. In addition, the first edge E1 of the upper semiconductor chip may be self-aligned with the alignment pattern line APL, for example, the first trench T1, on the upper surface of the lower semiconductor chip. As described above, the semiconductor chips are coupled to each other without an adhesive layer, and the total thickness of the semiconductor package 100 may be reduced or the thickness of each of the semiconductor chips may be increased. In addition, the semiconductor chips are self-aligned with and stacked on each other, and the stack precision of the semiconductor chips may be improved in the chip stack structure 120 of the semiconductor package 100.

In the semiconductor package 100, the structure in which the semiconductor chips are self-aligned with and stacked on each other without an adhesive layer may be applied not only to a semiconductor package including a chip stack structure in the form of general steps, but also to a semiconductor package including a chip stack structure in the form of Z-shaped steps or a semiconductor package including a chip stack structure in the form of zigzag. In addition, the structure in which the semiconductor chips are self-aligned with and stacked on each other without an adhesive layer is not limited to the chip stack structure in the form of steps or zigzag, and this structure may also be applied to semiconductor packages including other types of chip stack structures in which semiconductor chips are stacked on each other with chip pads exposed.

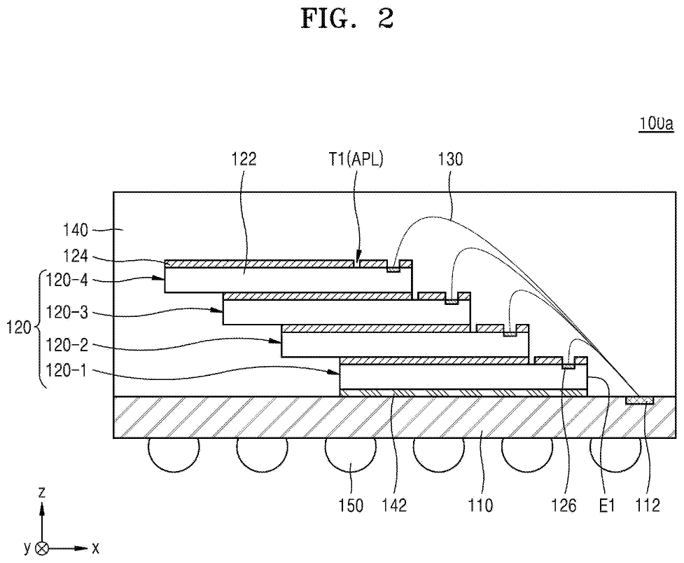

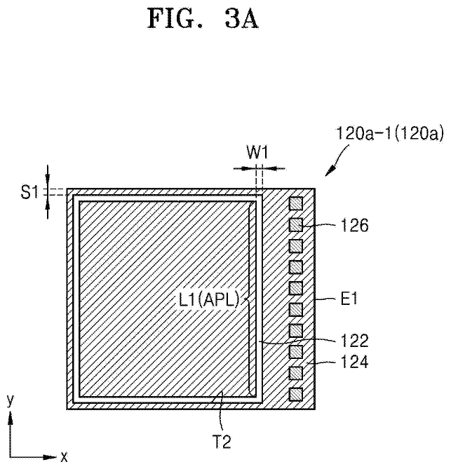

FIG. 2 is a cross-sectional view of an example of a semiconductor package 100a according to some implementations. The descriptions provided above with reference to FIGS. 1A and 1B are briefly given or omitted. In FIG. 2, the semiconductor package 100a may be different from the semiconductor package 100 of FIG. 1A, in that a chip stack structure 120 of FIG. 2 is stacked on the upper surface of a package substrate 110 through an adhesive layer 142. For example, the semiconductor package 100a may include a package substrate 110, a chip stack structure 120, a sealing material 140, and an external connection terminal 150. The package substrate 110, the sealing material 140, and the external connection terminal 150 are the same as those of the semiconductor package 100 described above with reference to FIG. 1A.

The chip stack structure 120 may include four semiconductor chips 120-1 to 120-4, and the four semiconductor chips 120-1 to 120-4 may be stacked in the form of steps. Also, the chip stack structure 120 may be adhered and fixed to the upper surface of the package substrate 110 through the adhesive layer 142. For example, the first semiconductor chip 120-1 of the chip stack structure 120 may be adhered and fixed to the upper surface of the package substrate 110 through the adhesive layer 142. Other features of the chip stack structure 120 are the same as those of the semiconductor package 100 described above with reference to FIG. 1A. Accordingly, in the semiconductor package 100a, each of the second to fourth semiconductor chips 120-2 to 120-4 of the chip stack structure 120 may be self-aligned with and stacked on the corresponding lower semiconductor chip without an adhesive layer.

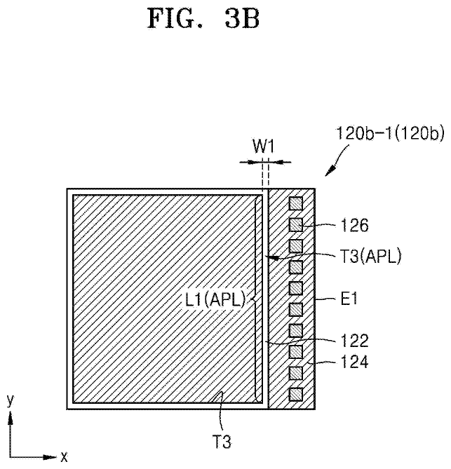

FIGS. 3A and 3B are plan views of examples of semiconductor chips included in the semiconductor package 100 of FIG. 1A according to some implementations. A description is given below with reference to FIG. 1A together, and descriptions provided above with reference to FIGS. 1A to 2 are simplified or omitted. In FIG. 3A, in the semiconductor package 100, a semiconductor chip of a chip stack structure 120a may be different from the semiconductor chip of the chip stack structure 120 of the semiconductor package 100 of FIG. 1A. Specifically, in the semiconductor package 100, the chip stack structure 120a may include four semiconductor chips 120a-1 to 120a-4 which are stacked in the form of steps, similar to the chip stack structure 120 of FIG. 1A. However, the stacking form of the chip stack structure 120a is not limited to the form of steps, and the number of semiconductor chips of the chip stack structure 120a is not limited to four. FIG. 3A shows a first semiconductor chip 120a-1, which is one of the four semiconductor chips 120a-1 to 120a-4 of the chip stack structure 120a.

The first semiconductor chip 120a-1 may include a chip body layer 122, a chip protective layer 124, and a chip pad 126. An alignment pattern line APL may be formed on the upper surface of the first semiconductor chip 120a-1. The alignment pattern line APL may be formed by a portion of a second trench T2. For example, the second trench T2 having a quadrangular ring shape may be formed in the upper surface of the first semiconductor chip 120a-1. The second trench T2 may pass through (extends into) the chip protective layer 124, and the chip body layer 122 may be exposed at the bottom of the second trench T2. The second trench T2 may include four lines that correspond to four edges on the upper surface of the first semiconductor chip 120a-1. Among the four lines of the second trench T2, a first line L1 adjacent to a first edge E1 of the first semiconductor chip 120a-1 and extending in the y-direction parallel to the first edge E1 may form the alignment pattern line APL.

In some implementations, the second trench T2 may have a first width W1 in a direction perpendicular to the direction in which the second trench T2 extends. For example, lines extending in the y-direction may have the first width W1 in the x-direction and lines extending in the x-direction may have the first width W1 in the y-direction. The first width W1 may be, for example, about 10 μm. However, the first width W1 of the second trench T2 is not limited to 10 μm. For example, except for the first line L1, other lines of the second trench T2 may be spaced apart from the corresponding edges of the first semiconductor chip 120a-1 by a first distance S1. The first distance S1 may be, for example, about 10 μm. However, the first distance S1 is not limited to 10 μm.

In the semiconductor package 100, the semiconductor chips of the chip stack structure 120a may also be self-aligned with and stacked on each other without an adhesive layer. For example, in the chip stack structure 120a, there is no adhesive layer between a second semiconductor chip 120a-2 and the first semiconductor chip 120a-1, and the second semiconductor chip 120a-2 and the first semiconductor chip 120a-1 may be directly coupled to each other by van der Waals force. Also, a first edge E1 of the second semiconductor chip 120a-2 may be self-aligned with the alignment pattern line APL of the first semiconductor chip 120a-1. For example, the first edge E1 of the second semiconductor chip 120a-2 may be self-aligned with the first line L1 of the second trench T2 of the first semiconductor chip 120a-1. Also, a stack structure between a third semiconductor chip 120a-3 and the second semiconductor chip 120a-2 and a stack structure between a fourth semiconductor chip 120a-4 and the third semiconductor chip 120a-3 may be substantially the same as the stack structure between the second semiconductor chip 120a-2 and the first semiconductor chip 120a-1.

In FIG. 3B, in the semiconductor package 100, a semiconductor chip of a chip stack structure 120b may be different from the semiconductor chip of the chip stack structure 120 of the semiconductor package 100 of FIG. 1A. For example, in the semiconductor package 100, the chip stack structure 120b may include four semiconductor chips 120b-1 to 120b-4 which are stacked in the form of steps, similar to the chip stack structure 120 of FIG. 1A. However, the stacking form of the chip stack structure 120b is not limited to the form of steps, and the number of semiconductor chips of the chip stack structure 120b is not limited to four. FIG. 3B shows a first semiconductor chip 120b-1, which is one of the four semiconductor chips 120b-1 to 120b-4 of the chip stack structure 120b.

The first semiconductor chip 120b-1 may include a chip body layer 122, a chip protective layer 124 and a chip pad 126. An alignment pattern line APL may be formed on the upper surface of the first semiconductor chip 120b-1. The alignment pattern line APL may be formed by a portion of a third trench T3. For example, the third trench T3 having a quadrangular ring shape may be formed in the upper surface of the first semiconductor chip 120b-1. The third trench T3 may pass through the chip protective layer 124, and the chip body layer 122 may be exposed at the bottom of the third trench T3. The third trench T3 may include four lines that correspond to four edges on the upper surface of the first semiconductor chip 120b-1. Among the four lines of the third trench T3, a first line L1 adjacent to a first edge E1 of the first semiconductor chip 120b-1 and extending in the y-direction parallel to the first edge E1 may form the alignment pattern line APL.

In some implementations, the third trench T3 may have a first width W1 in a direction perpendicular to the direction in which the third trench T3 extends. For example, lines extending in the y-direction may have the first width W1 in the x-direction and lines extending in the x-direction may have the first width W1 in the y-direction. The first width W1 may be, for example, about 10 μm. However, the first width W1 of the third trench T3 is not limited to 10 μm. Here, except for the first line L1, other lines of the third trench T3 may expose the corresponding edges of the first semiconductor chip 120b-1. For example, the upper surface portions of the remaining edges of the first semiconductor chip 120b-1 other than the first edge E1 may not be covered by the chip protective layer 124 in an amount of the first width W1 but exposed through the third trench T3.

In the semiconductor package 100, the semiconductor chips of the chip stack structure 120b may also be self-aligned with and stacked on each other without an adhesive layer. For example, there may be no adhesive layer between a second semiconductor chip 120b-2 and the first semiconductor chip 120b-1 in the chip stack structure 120b. In addition, the first edge E1 of the second semiconductor chip 120b-2 may be self-aligned with the alignment pattern line APL of the first semiconductor chip 120b-1, for example, to the first line L1 of the third trench T3.

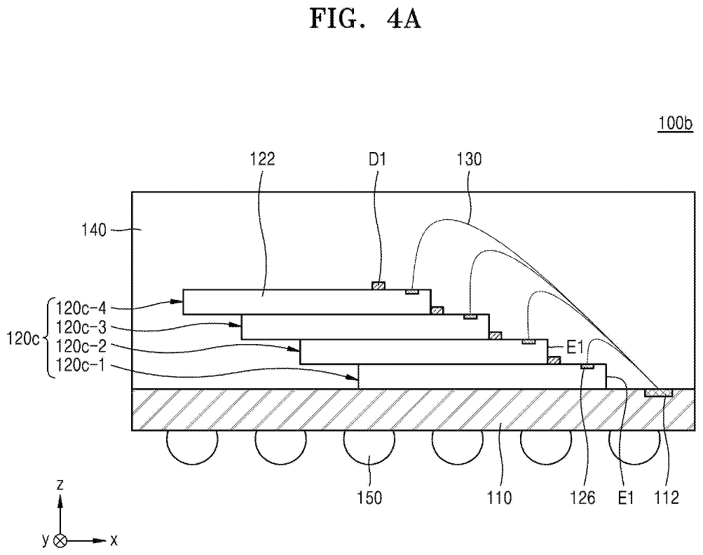

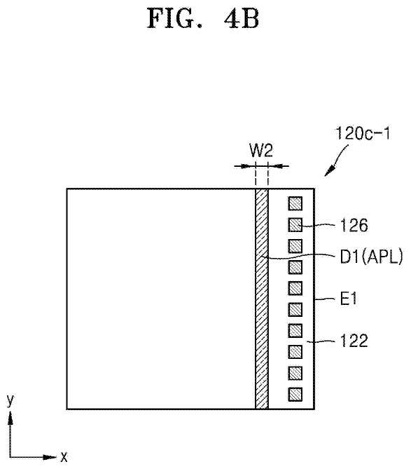

FIG. 4A is a cross-sectional view of an example of a semiconductor package 100b according to some implementations, and FIG. 4B is a plan view of an example of a semiconductor chip included in the semiconductor package 100b of FIG. 4A. The descriptions already given with reference to FIGS. 1A to 3B are briefly given or omitted. In FIGS. 4A and 4B, the semiconductor package 100b may be different from the semiconductor package 100 of FIG. 1A in terms of the configuration of a chip stack structure 120c. For example, the semiconductor package 100b may include a package substrate 110, a chip stack structure 120c, a scaling material 140, and an external connection terminal 150. In some implementations, the package substrate 110, the sealing material 140, and the external connection terminal 150 are the same as those of the semiconductor package 100 described above with reference to FIG. 1A.

In the semiconductor package 100b, the chip stack structure 120c may include four semiconductor chips 120c-1 to 120c-4 which are stacked in the form of steps, similar to the chip stack structure 120 of FIG. 1A. However, the stacking form of the chip stack structure 120c is not limited to the form of steps, and the number of semiconductor chips of the chip stack structure 120c is not limited to four. FIG. 4B shows a first semiconductor chip 120c-1, which is one of the four semiconductor chips 120c-1 to 120c-4 of the chip stack structure 120c.

The first semiconductor chip 120c-1 includes a chip body layer 122 and a chip pad 126 but may not include a separate chip protective layer on the upper surface thereof. Accordingly, the upper surface of the first semiconductor chip 120c-1 may correspond to the upper surface of the chip body layer 122. Also, in the semiconductor package 100b, the upper surface of the first semiconductor chip 120c-1, that is, the upper surface of the chip body layer 122, may be hydrophilic. For example, the upper surface of the first semiconductor chip 120c-1 may be plasma-treated and have hydrophilicity.

An alignment pattern line APL may be formed on the upper surface of the first semiconductor chip 120c-1. The alignment pattern line APL may be formed as a first dam D1 having a line shape. For example, the first dam D1 may be formed as a line shape on the upper surface of the chip body layer 122. Also, the first dam D1 may be adjacent to a first edge E1 of the first semiconductor chip 120c-1 in the x-direction and extend in the y-direction parallel to the first edge E1. The first dam D1 may have a structure that protrudes from the upper surface of the chip body layer 122 in a line shape. The first dam D1 may be include PI, for example, PSPI. However, the material of the first dam D1 is not limited to the PI or PSPI.

In some implementations, the first dam D1 may have a second width W2 in a direction perpendicular to the direction in which the first dam D1 extends. For example, the first dam D1 may extend in the y-direction and have the second width W2 in the x-direction. The second width W2 may be, for example, about 20 μm. However, the second width W2 of the first dam D1 is not limited to 20 μm.

In the semiconductor package 100b, the semiconductor chips of the chip stack structure 120c may also be self-aligned with and stacked on each other without an adhesive layer. For example, in the chip stack structure 120c, there is no adhesive layer between a second semiconductor chip 120c-2 and the first semiconductor chip 120c-1, and the second semiconductor chip 120c-2 and the first semiconductor chip 120c-1 may be directly coupled to each other by van der Waals force. Also, a first edge E1 of the second semiconductor chip 120c-2 may be self-aligned with the alignment pattern line APL of the first semiconductor chip 120c-1. For example, the first edge E1 of the second semiconductor chip 120c-2 may be self-aligned with the first dam D1 of the first semiconductor chip 120c-1. Also, the stack structure between a third semiconductor chip 120c-3 and the second semiconductor chip 120c-2 and the stack structure between a fourth semiconductor chip 120c-4 and the third semiconductor chip 120c-3 may be substantially the same as the stack structure between the second semiconductor chip 120c-2 and the first semiconductor chip 120c-1.

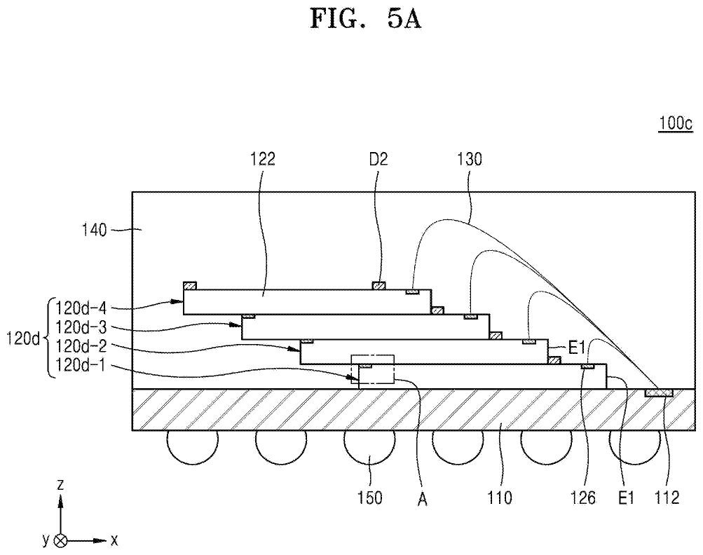

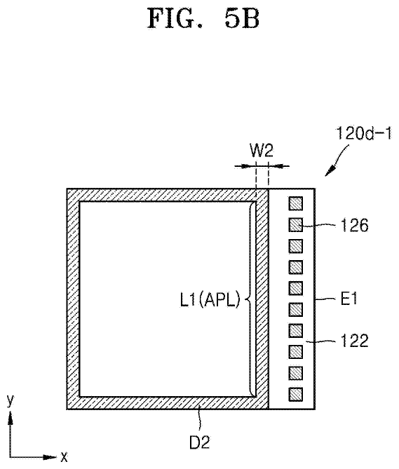

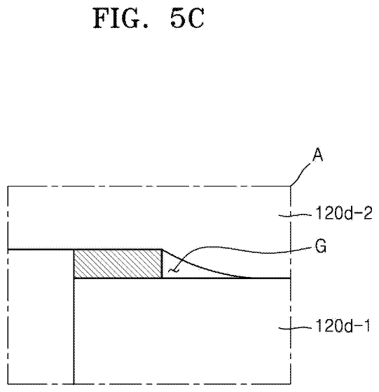

FIG. 5A is a cross-sectional view of an example of a semiconductor package 100c according to some implementations, FIG. 5B is a plan view of an example of a semiconductor chip included in the semiconductor package 100c of FIG. 5A according to some implementations, and FIG. 5C is an enlarged view of region A of FIG. 5A according to some implementations. The descriptions already given with reference to FIGS. 1A to 4B are briefly given or omitted.

In FIGS. 5A and 5B, the semiconductor package 100c may be different from the semiconductor package 100 of FIG. 1A in terms of the configuration of a chip stack structure 120d. For example, the semiconductor package 100c may include a package substrate 110, a chip stack structure 120d, a scaling material 140, and an external connection terminal 150. In some implementations, the package substrate 110, the sealing material 140, and the external connection terminal 150 may be the same as those of the semiconductor package 100 described above with reference to FIG. 1A.

In the semiconductor package 100c, the chip stack structure 120d may include four semiconductor chips 120d-1 to 120d-4 which are stacked in the form of steps, similar to the chip stack structure 120 of FIG. 1A. However, the stacking form of the chip stack structure 120d is not limited to the form of steps, and the number of semiconductor chips of the chip stack structure 120d is not limited to four. FIG. 5B shows a first semiconductor chip 120d-1, which is one of the four semiconductor chips 120d-1 to 120d-4 of the chip stack structure 120d.

The first semiconductor chip 120d-1 includes a chip body layer 122 and a chip pad 126 but may not include a separate chip protective layer on the upper surface thereof. Accordingly, the upper surface of the first semiconductor chip 120d-1 may correspond to the upper surface of the chip body layer 122. Also, in the semiconductor package 100c, the upper surface of the first semiconductor chip 120d-1, that is, the upper surface of the chip body layer 122, may be hydrophilic. For example, the upper surface of the first semiconductor chip 120d-1 may be plasma-treated and have hydrophilicity.

An alignment pattern line APL may be formed on the upper surface of the first semiconductor chip 120d-1. The alignment pattern line APL may be formed by a portion of a second dam D2 having a quadrangular ring shape. For example, the second dam D2 may be formed as a quadrangular ring shape protruding on the upper surface of the chip body layer 122. The second dam D2 may include four lines that correspond to four edges on the upper surface of the first semiconductor chip 120d-1. Among the four lines of the second dam D2, a first line L1 adjacent to a first edge E1 of the first semiconductor chip 120d-1 and extending in the y-direction parallel to the first edge E1 may form the alignment pattern line APL.

In some implementations, the second dam D2 may have a second width W2 in a direction perpendicular to the direction in which the second dam D2 extends. For example, lines extending in the y-direction may have the second width W2 in the x-direction and lines extending in the x-direction may have the second width W2 in the y-direction. The second width W2 may be, for example, about 20 μm. However, the second width W2 of the second dam D2 is not limited to 20 μm. Here, except for the first line L1, other lines of the second dam D2 may cover the corresponding edges of the first semiconductor chip 120d-1. For example, the upper surface portions of the remaining edges of the first semiconductor chip 120d-1 other than the first edge E1 may be covered by the second dam D2 in an amount of the second width W2.

As can shown in FIG. 5C, a gap G may exist between a second semiconductor chip 120d-2 and the first semiconductor chip 120d-1 due to the protruding structure of the second dam D2, and the gap G may be adjacent to the remaining lines of the second dam D2 other than the first line L1 adjacent to the first edge E1 of the first semiconductor chip 120d-1. For example, the gap G having a size of the protruding thickness of the second dam D2 exists adjacent to the remaining lines of the second dam D2, and the gap G may gradually decrease in a direction toward the inside of the second dam D2.

In the semiconductor package 100c, the semiconductor chips of the chip stack structure 120d may also be self-aligned with and stacked on each other without an adhesive layer. For example, in the chip stack structure 120d, there is no adhesive layer between the second semiconductor chip 120d-2 and the first semiconductor chip 120d-1, and the second semiconductor chip 120d-2 and the first semiconductor chip 120d-1 may be directly coupled to each other by van der Waals force. Also, a first edge E1 of the second semiconductor chip 120d-2 may be self-aligned with the alignment pattern line APL of the first semiconductor chip 120d-1. For example, the first edge E1 of the second semiconductor chip 120d-2 may be self-aligned with the first line L1 of the second dam D2 of the first semiconductor chip 120d-1. Also, the stack structure between a third semiconductor chip 120d-3 and the second semiconductor chip 120d-2 and the stack structure between a fourth semiconductor chip 120d-4 and the third semiconductor chip 120d-3 may be substantially the same as the stack structure between the second semiconductor chip 120d-2 and the first semiconductor chip 120d-1.

FIGS. 6A and 6B are cross-sectional views of examples of semiconductor packages 100d and 100e according to some implementations. The descriptions already given with reference to FIGS. 1A to 5B are briefly given or omitted.

In FIG. 6A, the semiconductor package 100d may be different from the semiconductor package 100 of FIG. 1A with respect to the configuration of a chip stack structure 120c. For example, the semiconductor package 100d may include a package substrate 110, a chip stack structure 120e, a sealing material 140, and an external connection terminal 150. In some implementations, the package substrate 110, the sealing material 140, and the external connection terminal 150 may be the same as those of the semiconductor package 100 described above with reference to FIG. 1A. For reference, the wire 130, and the sealing material 140 are omitted in FIG. 6A for convenience of illustration, and these components are also omitted in FIG. 6B.

In the semiconductor package 100d, the chip stack structure 120e may include eight semiconductor chips 120-1 to 120-8 which are stacked in the form of steps, unlike the chip stack structure 120 of FIG. 1A. Each of the eight semiconductor chips 120-1 to 120-8 (or referred to as first to eight semiconductor chips 120-1 to 120-8) may be substantially the same as the first semiconductor chip 120-1 of FIG. 1B. In addition, in the semiconductor package 100d, the semiconductor chips of the chip stack structure 120e may be stacked in a step shape in the x-direction and stacked in a Z shape in the z-direction. For example, in the chip stack structure 120e of the semiconductor package 100d, the first to fifth semiconductor chips 120-1 to 120-5 may be stacked on each other while the positions thereof increase to the left in the x-direction and the sixth to eighth semiconductor chips 120-6 to 120-8 may be stacked on each other while the positions thereof increase to the right in the x-direction.

As described above, when a large number of semiconductor chips are stacked in a step shape in one direction only, the width of the semiconductor package in the one direction may significantly increase. For example, when semiconductor chips are stacked on a package substrate in a step shape toward only one side in the x-direction, the width of the semiconductor package in the x-direction may significantly increase. However, in the semiconductor package 100d, the semiconductor chips of the chip stack structure 120e are stacked in a step shape in the x-direction and also arranged in a Z shape in the z-direction, and the width of the semiconductor package 100d in the x-direction may not increase compared to the width of the semiconductor package 100 of FIG. 1A in the x-direction.

In FIG. 6B, the semiconductor package 100e may be different from the semiconductor package 100 of FIG. 1A with respect to the configuration of a chip stack structure 120f. For example, the semiconductor package 100e may include a package substrate 110, a chip stack structure 120f, a sealing material 140, and an external connection terminal 150. In some implementations, the package substrate 110, the sealing material 140, and the external connection terminal 150 may be the same as those of the semiconductor package 100 described above with reference to FIG. 1A.

In the semiconductor package 100e, the chip stack structure 120f may include four semiconductor chips 120-1 to 120-4, like the chip stack structure 120 of FIG. 1A. Also, each of the four semiconductor chips 120-1 to 120-4 may be substantially the same as the first semiconductor chip 120-1 of FIG. 1B. However, unlike the chip stack structure 120 of FIG. 1A, the chip stack structure 120f may have a zigzag shape rather than a step shape. For example, the first semiconductor chip 120-1 and the third semiconductor chip 120-3 may be arranged biased to the left in the x-direction and the second semiconductor chip 120-2 and the fourth semiconductor chip 120-4 may be arranged biased to the right in the x-direction. In the semiconductor package 100c, as the four semiconductor chips 120-1 to 120-4 of the chip stack structure 120f are stacked in a zigzag shape, the width of the semiconductor package 100e in the x-direction may be minimized.

FIGS. 6A and 6B respectively illustrate an example of a chip stack structure that includes eight semiconductor chips and having a Z-step shape, and an example of a chip stack structure that includes four semiconductor chips and having a zigzag shape. However, the number of semiconductor chips in the chip stack structure having the form of Z-shaped steps and the number of semiconductor chips in the chip stack structure having the form of zigzag are not limited to the above-mentioned values.

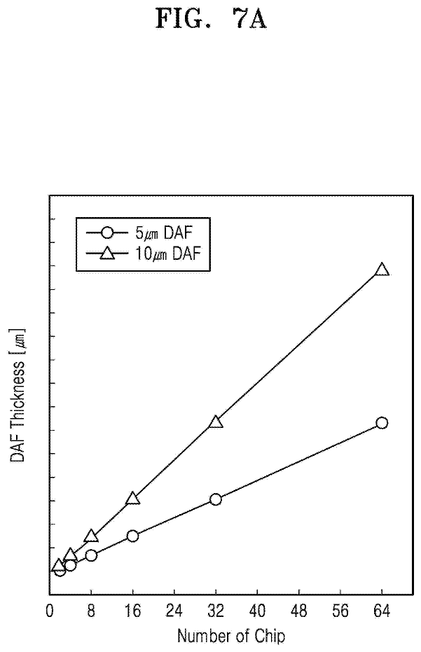

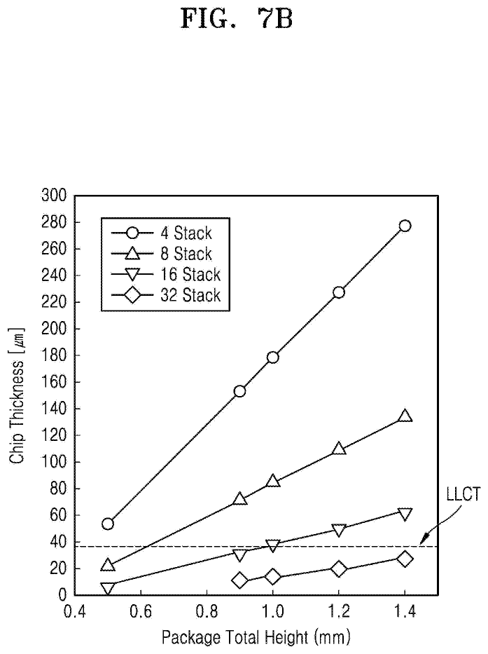

FIG. 7A is a graph showing thicknesses of DAF versus the numbers of semiconductor chips according to some implementations, and FIG. 7B is a graph showing chip thicknesses according to various chip stack structures with respect to the total heights of semiconductor packages according to some implementations. In FIG. 7A, when stacking a semiconductor chip on a package substrate or on another semiconductor chip, a DAF may be generally used as an adhesive layer. FIG. 7A shows that, as the number of semiconductor chips increases in the chip stack structure, the total thickness of the DAFs increases. In addition, FIG. 7A shows that the total thickness of the DAFs in the chip stack structure also varies significantly due to the difference in the thickness of one DAF. For example, when the thickness of one DAF is 5 μm, the total thickness of DAFs in a chip stack structure including 8 semiconductor chips may be 40 μm and the total thickness of DAFs in a chip stack structure including 16 semiconductor chips may be 80 μm. Also, when the thickness of one DAF is 10 μm, the total thickness of DAFs in a chip stack structure including 8 semiconductor chips may be 80 μm and the total thickness of DAFs in a chip stack structure including 16 semiconductor chips may be 160 μm. Accordingly, in a chip stack structure using DAFs, as the number of semiconductor chips increases, the total thickness of the semiconductor package may be increased by the DAFs.

In FIG. 7B, the total heights of semiconductor packages including chip stack structures of 4 stacks, 8 stacks, 16 stacks, and 32 stacks are shown depending on the thicknesses of the semiconductor chips. Here, the chip thickness limit line (LLCT) indicated by a dashed line represents the minimum thickness of a chip that may be used in a semiconductor package. For example, a semiconductor chip with a thickness less than LLCT may not be used in a semiconductor package.

In FIG. 7B, in a semiconductor package that includes a chip stack structure of 4 stacks, all semiconductor packages with a height of 0.5 mm or more may be manufactured. For example, a semiconductor package with a height of 0.5 mm may be manufactured by stacking four semiconductor chips each having a thickness of about 60 μm. Also, a semiconductor package with a height of 1.4 mm may be manufactured by stacking four semiconductor chips each having a thickness of about 280 μm.

In a semiconductor package that includes a chip stack structure of 8 stacks, only a semiconductor package with a height of 0.9 mm or more may be manufactured. For example, a semiconductor package with a height of 0.9 mm may be manufactured by stacking eight semiconductor chips each having a thickness of about 70 μm. Also, a semiconductor package with a height of 1.4 mm may be manufactured by stacking eight semiconductor chips each having a thickness of about 140 μm.

In a semiconductor package that includes a chip stack structure of 16 stacks, only a semiconductor package with a height of 1.0 mm or more may be manufactured. For example, a semiconductor package with a height of 1.0 mm may be manufactured by stacking 16 semiconductor chips each having a thickness of about the LLCT. Also, a semiconductor package with a height of 1.4 mm may be manufactured by stacking 16 semiconductor chips each having a thickness of about 60 μm.

In a semiconductor package that includes a chip stack structure of 32 stacks, a semiconductor package even with a height of 1.4 mm may not be manufactured. For example, 32 semiconductor chips, each having a thickness of 30 μm, have to be stacked in order to manufacture a semiconductor package with a height of 1.4 mm. However, the thickness of 30 μm is less than LLCT, the semiconductor chip with a thickness of 30 μm may not be used in a semiconductor package.

In a semiconductor package that includes a chip stack structure, when the number of semiconductor chips is fixed, the total height of the semiconductor package may be reduced by removing the adhesive layer, such as the DAF. Conversely, when the total height of the semiconductor package is fixed, the number of semiconductor chips may be increased by removing the adhesive layer. Also, when the number of semiconductor chips and the total height of the semiconductor package is fixed, the thicknesses of semiconductor chips may be increased by removing the adhesive layer. Accordingly, the semiconductor packages 100 and 100a to 100e according to some implementations may contribute to at least one of reducing the total height of the semiconductor package, maximizing the number of semiconductor chips, and maximizing the thickness of the semiconductor chip.

Additionally, in general chip stacking processes, a minimum design rule may be required for chip-to-chip due to a die-attach tolerance. For example, a tolerance of about 25 μm is required when stacking the same type of chips and a tolerance of about 50 μm is required when stacking different types of chips. This tolerance increases the size of the semiconductor package in a horizontal direction, and as the number of semiconductor chips increases, the size of the semiconductor package in the horizontal direction may further increase. On the other hand, in the semiconductor packages 100 and 100a to 100e according to some implementations, the semiconductor chips are self-aligned with and stacked on each other without an adhesive layer. Accordingly, an increase in the size of the semiconductor package in the horizontal direction due to the die-attach tolerance may not occur.

FIG. 8A is a cross-sectional view of an example of a semiconductor package 100f according to some implementations, and FIG. 8B is a plan view of an example of a package substrate included in the semiconductor package 100f of FIG. 8A according to some implementations. The descriptions already given with reference to FIGS. 1A to 7B are briefly given or omitted.

In FIGS. 8A and 8B, the semiconductor package 100f may be different from the semiconductor package 100 of FIG. 1A with respect to the configuration of a package substrate 110a. For example, the semiconductor package 100f may include a package substrate 110a, a chip stack structure 120, a sealing material 140, and an external connection terminal 150. In some implementations, the chip stack structure 120, the sealing material 140, and the external connection terminal 150 may be the same as those of the semiconductor package 100 described above with reference to FIG. 1A. For reference, the wire 130, the scaling material 140, and the external connection terminal 150 are omitted in FIG. 8A for convenience of illustration.

In FIG. 8A, the package substrate 110a may include a substrate body layer 110B, a substrate protective layer 110SR, a substrate pad 112, and an external pad. The substrate body layer 110B, the substrate pad 112, and the external pad are the same as those of the semiconductor package 100 described above with reference to FIG. 1A.

The substrate protective layer 110SR may include, for example, a solder resist (SR), and more particularly a photo solder resist (PSR). However, the material of the substrate protective layer 110SR is not limited to the SR or PSR. In the semiconductor package 100f, the package substrate 110a may include an SR open region SROA formed in the substrate protective layer 110SR. The SR open region SROA may be formed by removing a portion of the substrate protective layer 110SR, and the upper surface of the substrate body layer 110B may be exposed through the SR open region SROA.

In some implementations, the SR open region SROA may have a size sufficient to accommodate a first semiconductor chip 120-1. For example, the planar area of the SR open region SROA may be substantially the same as or slightly greater than the planar area of the first semiconductor chip 120-1. Accordingly, the first semiconductor chip 120-1 or the chip stack structure 120 including the first semiconductor chip 120-1 may be inserted into and stacked in the SR open region SROA of the substrate protective layer 110SR.

In the semiconductor package 100f, the first semiconductor chip 120-1 may be stacked on the package substrate 110a without an adhesive layer. For example, in the SR open region SROA of the package substrate 110a, the first semiconductor chip 120-1 may be directly coupled to the substrate body layer 110B using van der Waals force without an adhesive layer. Also, for coupling to the first semiconductor chip 120-1 by van der Waals force, the upper surface of the substrate body layer 110B exposed through the SR open region SROA may be hydrophilic.

In some implementations, the SR open region SROA may have a rectangular shape corresponding to the rectangular shape of the lower surface of the first semiconductor chip 120-1. Accordingly, the SR open region SROA has four sides. Among the four sides, a first side SL1 extending in the y-direction and located on the right in the x-direction may act as an alignment pattern line APL. In some implementations, the first semiconductor chip 120-1 may be self-aligned with the package substrate 110a by the alignment pattern line APL. For example, a first edge E1 of the first semiconductor chip 120-1 may be self-aligned with the first side SL1 of the SR open region SROA.

In some implementations, the semiconductor package 100f is not limited to the structure in which the first semiconductor chip 120-1 is self-aligned with and stacked on the package substrate 110a using the SR open region SROA of the substrate protective layer 110SR without an adhesive layer. For example, similar to the semiconductor package 100 of FIG. 1A or FIG. 3A, the first semiconductor chip 120-1 may be self-aligned with and stacked on the package substrate 110a using a line-shaped trench or a quadrangular ring-shaped trench formed in the substrate protective layer 110SR without an adhesive layer. Accordingly, the hydrophilic treatment may be performed on the upper surface of the substrate protective layer 110SR.

FIGS. 9A to 13 are cross-sectional views and plan views showing an example of a process of manufacturing a semiconductor package according to some implementations. A description is given below with reference to FIGS. 1A and 1B together, and descriptions already given with reference to FIGS. 1A to 8B are simplified or omitted.

In FIGS. 9A and 9B, a semiconductor package manufacturing method, according to some implementations shows, for example, a process of manufacturing the semiconductor package 100 of FIG. 1A. In the semiconductor package manufacturing method, first, an alignment pattern line APL is formed on each of semiconductor chips. The alignment pattern line APL may include a first trench T1 having a line shape and formed in a chip protective layer 124 of the semiconductor chip. For example, the chip protective layer 124 may include PSPI, and the first trench T1 may be formed through an exposure process. In some implementations, the shape of the first trench T1 may ne the same as that described above with reference to FIG. 1A.

Prior to forming the alignment pattern line APL on each of the semiconductor chips, the hydrophilic treatment may be performed on the chip protective layer 124 of each of the semiconductor chips. The hydrophilic treatment may be performed, for example, through plasma treatment. The hydrophilicity may be imparted to the upper surface of the chip protective layer 124 of each of the semiconductor chips through the hydrophilic treatment. Also, during the hydrophilic treatment of the chip protective layers 124 of the semiconductor chips, the hydrophilic treatment may also be performed on the lower surfaces of the semiconductor chips. Here, the upper surface of the chip body layer 122 exposed through the alignment pattern line APL, for example, the first trench T1, may be hydrophobic.

After forming the alignment pattern line APL, a first semiconductor chip 120-1 is stacked on the package substrate 110. The first semiconductor chip 120-1 may be stacked on the package substrate 110 using an adhesive layer, the SR open region SROA (see FIG. 8A), or the like. When using the SR open region, the first semiconductor chip 120-1 may be stacked on the package substrate 110, without an adhesive layer, through a process similar to the process of stacking a second semiconductor chip 120-2, which is described below.

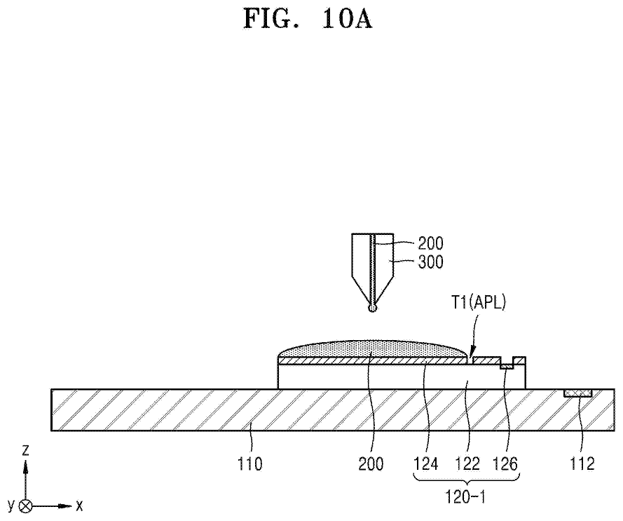

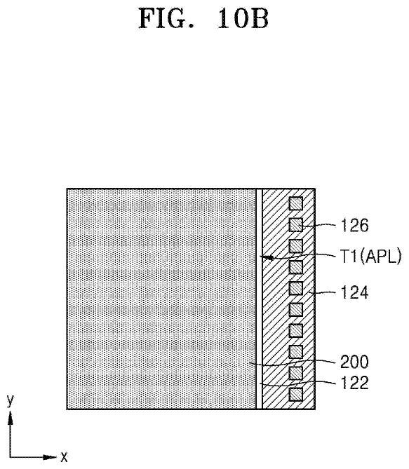

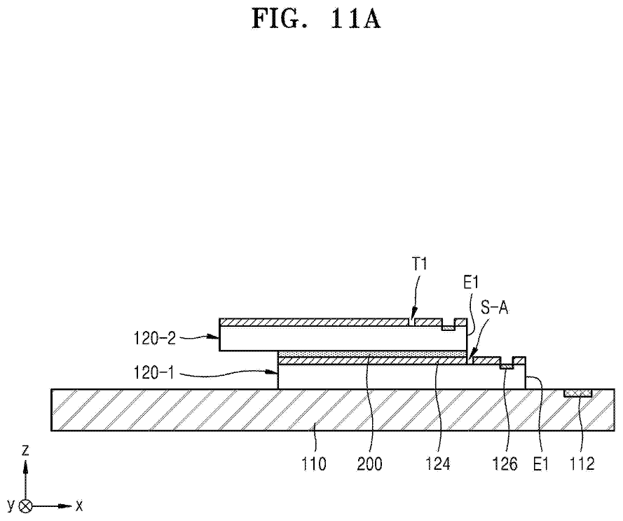

Subsequently, in FIGS. 10A and 10B, a hydrophilic liquid 200 is applied on the chip protective layer 124 of the first semiconductor chip 120-1 using a dispenser 300. For example, the hydrophilic liquid may include polar liquid substances, such as water and alcohol. Due to the hydrophilicity of the chip protective layer 124, such as PSPI, and the hydrophobicity inside the first trench T1 that is the alignment pattern line APL, the chip protective layer 124 may be wetted by the hydrophilic liquid 200 on the left side in the x-direction, based on the first trench T1, as shown in FIGS. 10A and 10B.

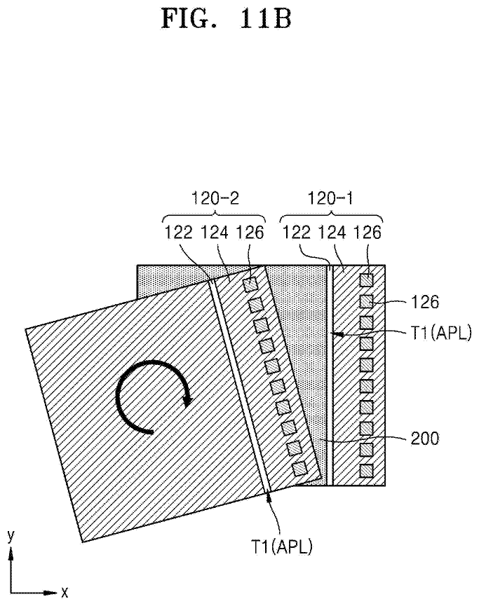

In FIGS. 11A and 11B, after the hydrophilic liquid 200 is applied, the second semiconductor chip 120-2 is stacked on the first semiconductor chip 120-1. As described above, the lower surface of the second semiconductor chip 120-2 may be hydrophilic. Accordingly, when stacking the second semiconductor chip 120-2, the lower surface of the second semiconductor chip 120-2 may be wetted by and coupled to the hydrophilic liquid 200 on the first semiconductor chip 120-1. Also, as indicated by a circular arrow in FIG. 11B, due to the surface tension of the hydrophilic liquid 200, the second semiconductor chip 120-2 may be automatically self-aligned with the first semiconductor chip 120-1 through rotational movement and/or straight-line movement. For example, a first edge E1 of the second semiconductor chip 120-2 may be self-aligned with the alignment pattern line APL, that is, the first trench T1 of the first semiconductor chip 120-1.

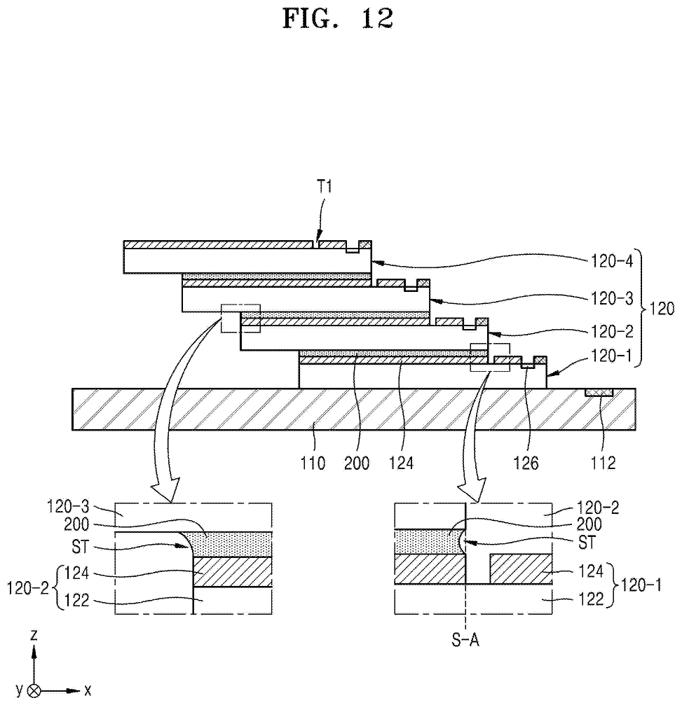

Subsequently, in FIGS. 12, through the same process, a third semiconductor chip 120-3 is stacked on the second semiconductor chip 120-2 and a fourth semiconductor chip 120-4 is stacked on the third semiconductor chip 120-3. The third semiconductor chip 120-3 may be self-aligned (S-A) to the second semiconductor chip 120-2 and the fourth semiconductor chip 120-4 may be self-aligned (S-A) to the third semiconductor chip 120-3. As shown in the enlarged view of FIG. 12, in a region near the first trench T1 of the first semiconductor chip 120-1, the hydrophilic liquid 200 may maintain an inwardly concave shape between the first semiconductor chip 120-1 and the second semiconductor chip 120-2 due to surface tension ST. Also, at the left end of the second semiconductor chip 120-2 in the x-direction, the hydrophilic liquid 200 becomes thinner in the upward direction with respect to the z-direction due to the surface tension ST and may maintain a shape protruding long to the left in the x-direction.

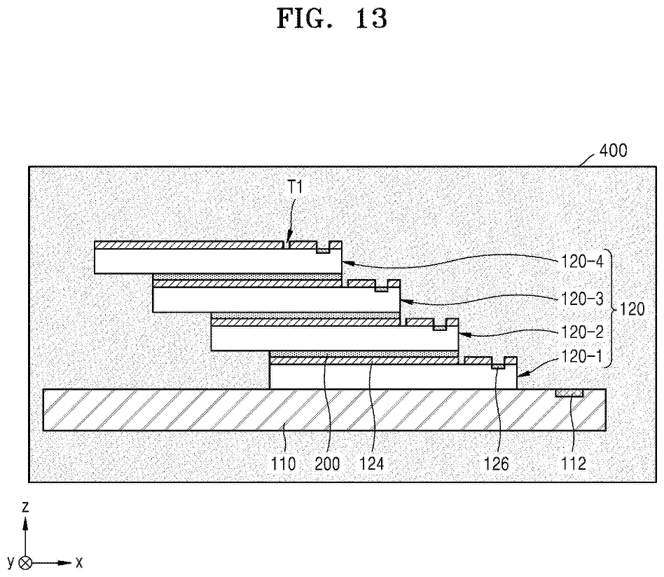

Subsequently, in FIG. 13, the package substrate 110 including the four semiconductor chips 120-1 to 120-4 is inserted into a chamber 400 and baked or heat-cured. The bake process may represent, for example, a heating process for removing the hydrophilic liquid 200. The hydrophilic liquid 200 is vaporized and removed through the baking process, and neighboring semiconductor chips may be directly coupled to each other by van der Waals force. For example, the first semiconductor chip 120-1 and the second semiconductor chip 120-2, the second semiconductor chip 120-2 and the third semiconductor chip 120-3, and the third semiconductor chip 120-3 and the fourth semiconductor chip 120-4 may be directly coupled to each other by van der Waals forces. Accordingly, the chip stack structure 120 may be formed in which the semiconductor chips are self-aligned with and stacked on the package substrate 110 without an adhesive layer. Subsequently, a wire 130, a sealing material 140, and an external connection terminal 150 may be formed, thereby completing the semiconductor package 100 of FIG. 1A.

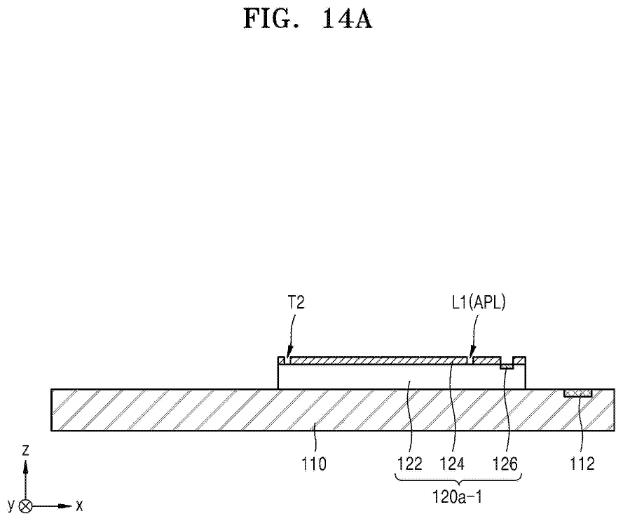

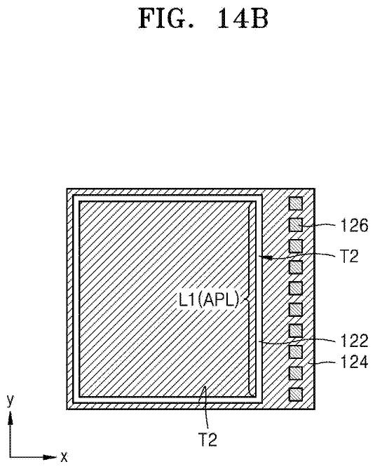

FIGS. 14A to 16B are cross-sectional views and plan views showing an example of a process of manufacturing a semiconductor package according to some implementations. A description is given below with reference to FIG. 3A together, and descriptions already given with reference to FIGS. 9A to 13 are simplified or omitted.

In FIGS. 14A and 14B, a semiconductor package manufacturing method according to some implementations shows, for example, a process of manufacturing the semiconductor package 100 of FIG. 3A according to some implementations. In the semiconductor package manufacturing method, first, an alignment pattern line APL is formed on each of semiconductor chips. The alignment pattern line APL may include a second trench T2 having a quadrangular ring shape and formed in a chip protective layer 124 of the semiconductor chip. For example, the chip protective layer 124 may include PSPI, and the second trench T2 may be formed through an exposure process. In some implementations, the shapes of the second trench T2 and a first line L1 of the second trench T2 may be the same as those of the semiconductor package 100 described above with reference to FIG. 3A.

Prior to forming the alignment pattern line APL on each of the semiconductor chips, the hydrophilic treatment may be performed on the chip protective layer 124 of each of the semiconductor chips. The hydrophilic treatment may be performed, for example, through plasma treatment. Also, during the hydrophilic treatment of the chip protective layers 124 of the semiconductor chips, the hydrophilic treatment may also be performed on the lower surfaces of the semiconductor chips. For example, the upper surface of the chip body layer 122 exposed through the second trench T2 including the alignment pattern line APL may be hydrophobic.

After forming the alignment pattern line APL, a first semiconductor chip 120a-1 is stacked on the package substrate 110. The first semiconductor chip 120a-1 may be stacked on the package substrate 110 using an adhesive layer, the SR open region SROA (see FIG. 8A), or the like.

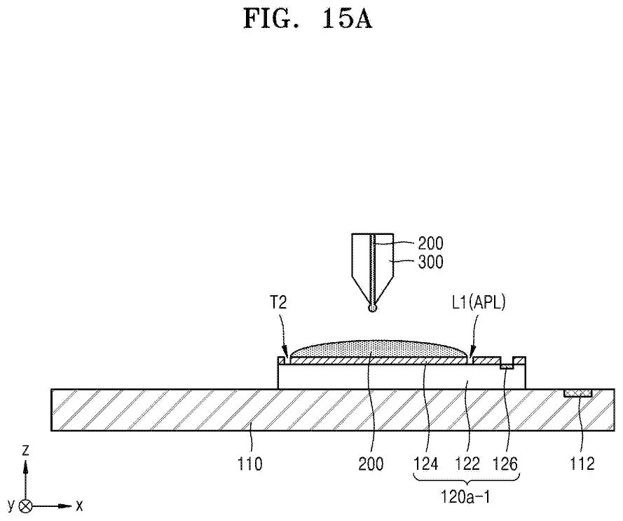

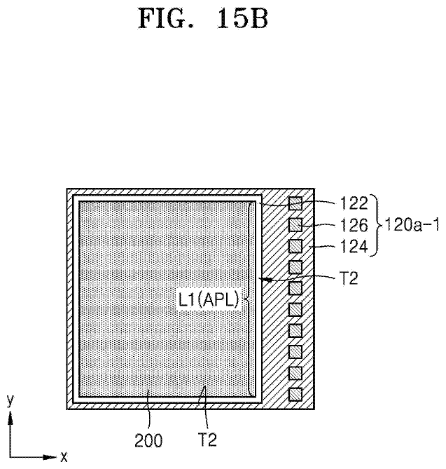

Subsequently, in FIGS. 15A and 15B, a hydrophilic liquid 200 is applied on the chip protective layer 124 of the first semiconductor chip 120a-1 using a dispenser 300. Due to the hydrophilicity of the chip protective layer 124 and the hydrophobicity in the second trench T2 including the alignment pattern line APL, the chip protective layer 124 inside the second trench T2 may be wetted by the hydrophilic liquid 200 as shown in FIGS. 15A and 15B.

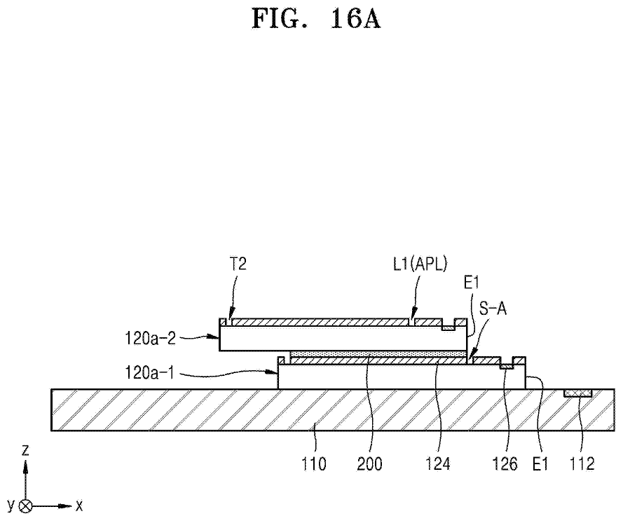

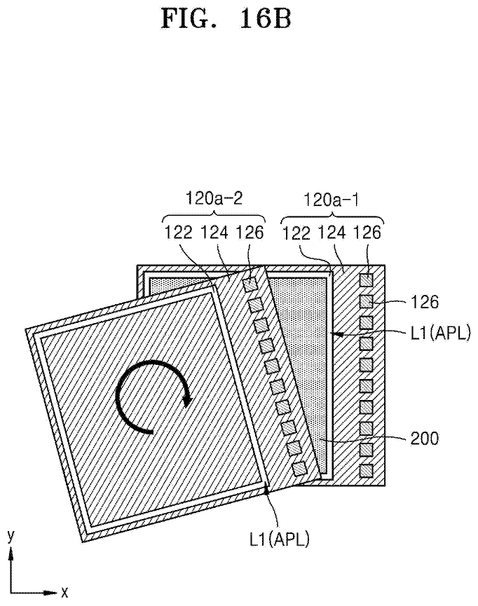

In FIGS. 16A and 16B, after the hydrophilic liquid 200 is applied, a second semiconductor chip 120a-2 is stacked on the first semiconductor chip 120a-1. As described above, the lower surface of the second semiconductor chip 120a-2 may be hydrophilic. Accordingly, when stacking the second semiconductor chip 120a-2, the lower surface of the second semiconductor chip 120a-2 may be wetted by and coupled to the hydrophilic liquid 200 on the first semiconductor chip 120a-1. Also, as indicated by a circular arrow in FIG. 16B, due to the surface tension of the hydrophilic liquid 200, the second semiconductor chip 120a-2 may be automatically self-aligned with the first semiconductor chip 120a-1 through rotational movement and/or straight-line movement. For example, a first edge E1 of the second semiconductor chip 120a-2 may be self-aligned with the alignment pattern line APL, that is, the first line L1 of the second trench T2 of the first semiconductor chip 120a-1.

Subsequently, a third semiconductor chip 120a-3 and a fourth semiconductor chip 120a-4 are stacked, and the chip stack structure 120a of FIG. 3A may be formed through a bake process. Also, a wire 130, a sealing material 140, and an external connection terminal 150 may be formed, thereby completing the semiconductor package 100 of FIG. 3A.

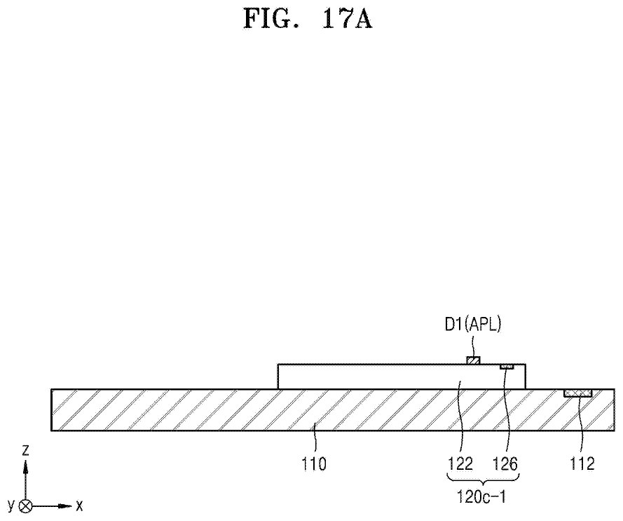

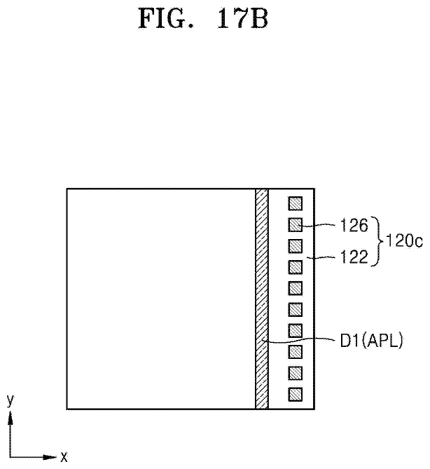

FIGS. 17A to 19B are cross-sectional views and plan views showing an example of a process of manufacturing a semiconductor package according to some implementations. A description is given below with reference to FIGS. 4A and 4B together, and descriptions already given with reference to FIGS. 9A to 13 are simplified or omitted.

In FIGS. 17A and 17B, a semiconductor package manufacturing method according to some implementations shows, for example, a process of manufacturing the semiconductor package 100b of FIG. 4A. In the semiconductor package manufacturing method, first, an alignment pattern line APL is formed on each of semiconductor chips. The alignment pattern line APL may include a first dam D1 having a line shape and formed in a chip body layer 122 of the semiconductor chip. For example, the first dam D1 may include PSPI and be formed through an exposure process. The shape of the first dam D1 is the same as that of the semiconductor package 100b of FIG. 4A.

Prior to forming the alignment pattern line APL on each of the semiconductor chips, the hydrophilic treatment may be performed on the upper surface of a chip body layer 122 of each of the semiconductor chips. The hydrophilic treatment may be performed, for example, through plasma treatment. Also, during the hydrophilic treatment of the upper surfaces of the chip body layers 122 of the semiconductor chips, the hydrophilic treatment may also be performed on the lower surfaces of the semiconductor chips. Here, the alignment pattern line APL, for example, the first dam D1, may be hydrophobic due to the material properties of PSPI.

After forming the alignment pattern line APL, a first semiconductor chip 120c-1 is stacked on the package substrate 110. The first semiconductor chip 120c-1 may be stacked on the package substrate 110 using an adhesive layer, the SR open region SROA (see FIG. 8A), or the like.

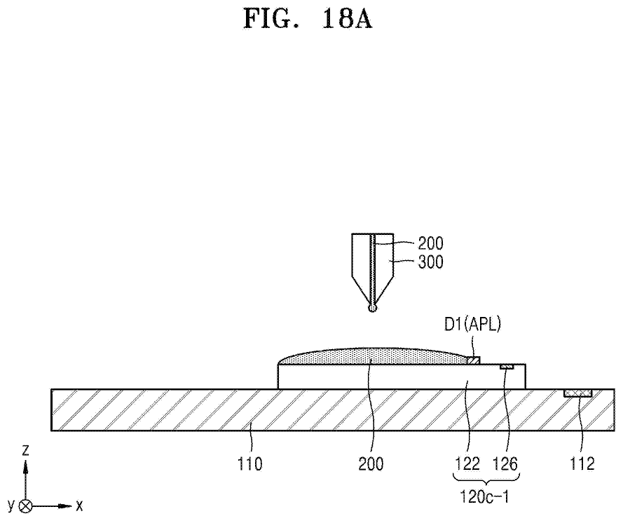

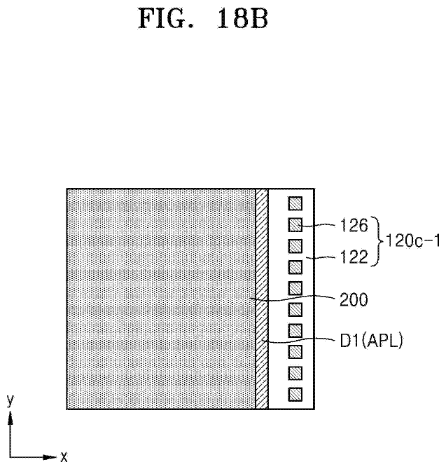

Subsequently, In FIGS. 18A and 18B, a hydrophilic liquid 200 is applied on the chip body layer 122 of the first semiconductor chip 120c-1 using a dispenser 300. Due to the hydrophilicity of the chip body layer 122 and the hydrophobicity of the first dam D1, the chip body layer 122 may be wetted by the hydrophilic liquid 200 on the left side in the x-direction, based on the first dam D1, as shown in FIGS. 18A and 18B.

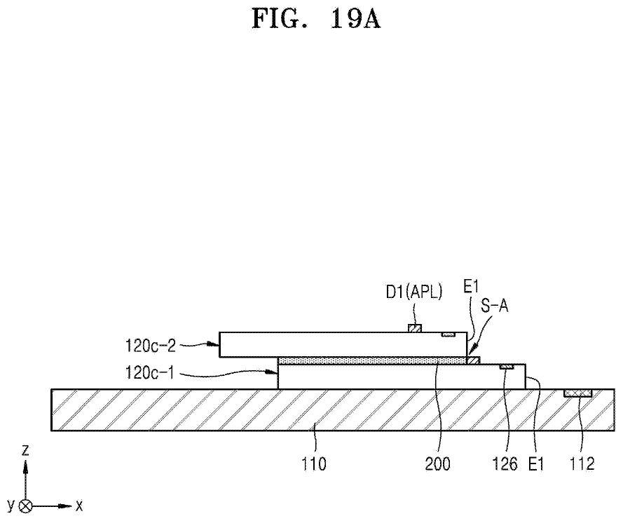

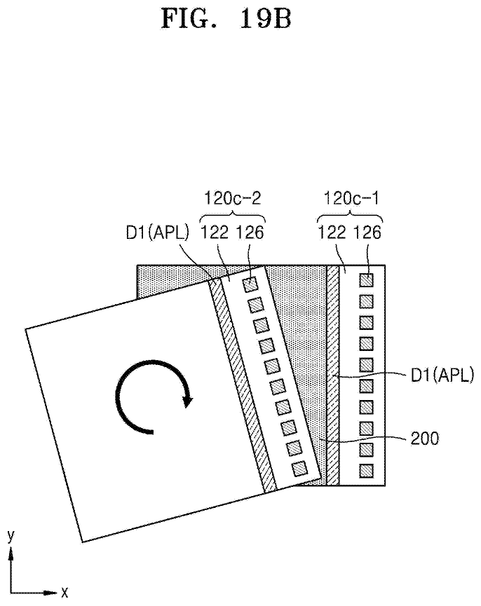

In FIGS. 19A and 19B, after the hydrophilic liquid 200 is applied, a second semiconductor chip 120c-2 is stacked on the first semiconductor chip 120c-1. As described above, the lower surface of the second semiconductor chip 120c-2 may be hydrophilic. Accordingly, when stacking the second semiconductor chip 120c-2, the lower surface of the second semiconductor chip 120c-2 may be wetted by and coupled to the hydrophilic liquid 200 on the first semiconductor chip 120c-1. Also, as indicated by a circular arrow in FIG. 19B, due to the surface tension of the hydrophilic liquid 200, the second semiconductor chip 120c-2 may be automatically self-aligned with the first semiconductor chip 120c-1 through rotational movement and/or straight-line movement. For example, a first edge E1 of the second semiconductor chip 120c-2 may be self-aligned with the alignment pattern line APL, that is, the first dam D1 of the first semiconductor chip 120c-1.

Subsequently, a third semiconductor chip 120c-3 and a fourth semiconductor chip 120c-4 are stacked, and the chip stack structure 120c of FIG. 4A may be formed through a bake process. Also, a wire 130, a sealing material 140, and an external connection terminal 150 may be formed, thereby completing the semiconductor package 100b of FIG. 4A.

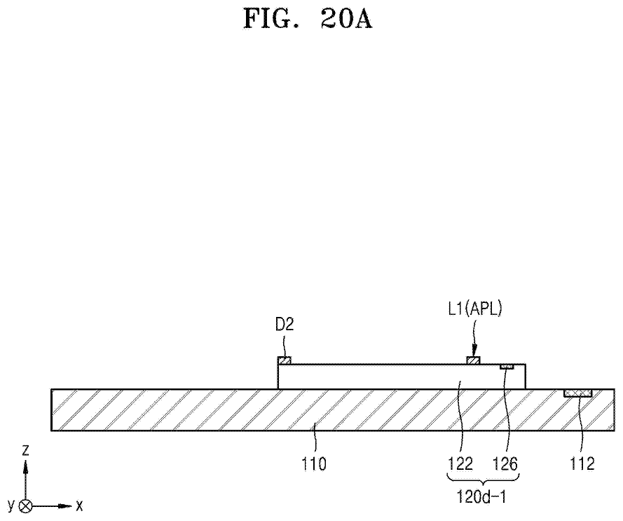

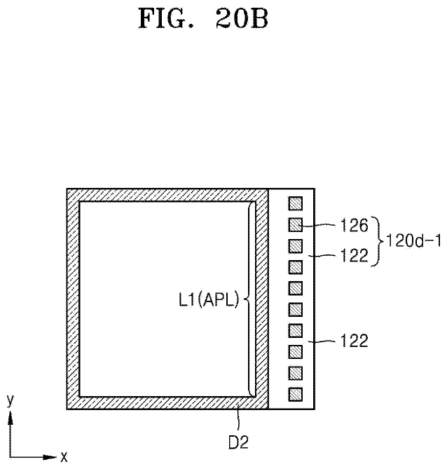

FIGS. 20A to 22B are cross-sectional views and plan views showing an example of a process of manufacturing a semiconductor package according to some implementations. A description is given below with reference to FIGS. 5A and 5B together, and descriptions already given with reference to FIGS. 9A to 13 are simplified or omitted.

In FIGS. 20A and 20B, a semiconductor package manufacturing method according to some implementations shows, for example, a process of manufacturing the semiconductor package 100c of FIG. 5A. In the semiconductor package manufacturing method, first, an alignment pattern line APL is formed on each of semiconductor chips. The alignment pattern line APL may include a second dam D2 having a quadrangular ring shape and formed in the chip body layer 122 of the semiconductor chip. For example, the second dam D2 may include PSPI and be formed through an exposure process. In some implementations, the shapes of the second dam D2 and a first line L1 of the second dam D2 may be the same as those of the semiconductor package 100c described above with reference to FIG. 5A.

Prior to forming alignment pattern lines APL on the semiconductor chips, the hydrophilic treatment may be performed on the upper surfaces of the chip body layers 122 of the semiconductor chips. The hydrophilic treatment may be performed, for example, through plasma treatment. Also, during the hydrophilic treatment of the upper surfaces of the chip body layers 122 of the semiconductor chips, the hydrophilic treatment may also be performed on the lower surfaces of the semiconductor chips. Here, the second dam D2 including the alignment pattern line APL may be hydrophobic due to the material properties of PSPI.

After forming the alignment pattern line APL, a first semiconductor chip 120d-1 is stacked on the package substrate 110. The first semiconductor chip 120d-1 may be stacked on the package substrate 110 using an adhesive layer, the SR open region SROA (see FIG. 8A), or the like.

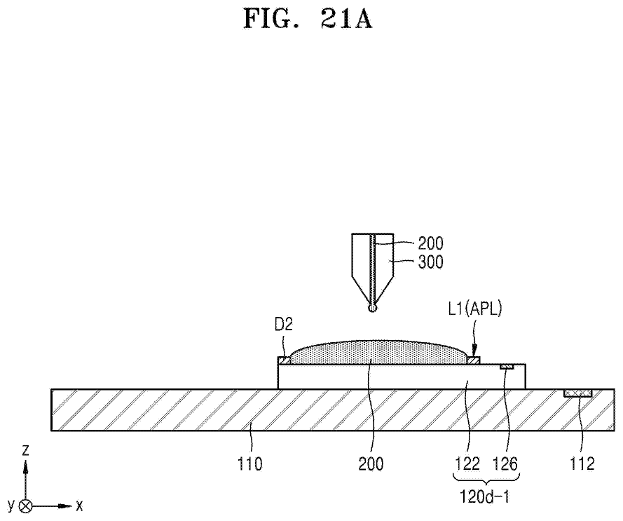

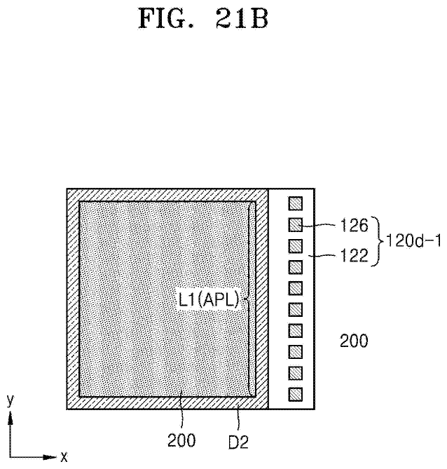

In FIGS. 21A and 21B, a hydrophilic liquid 200 is applied on the chip body layer 122 of the first semiconductor chip 120d-1 using a dispenser 300. Due to the hydrophilicity of the chip body layer 122 and the hydrophobicity of the second dam D2 including the alignment pattern line APL, the chip body layer 122 inside the second dam D2 may be wetted by the hydrophilic liquid 200 as shown in FIGS. 21A and 21B.

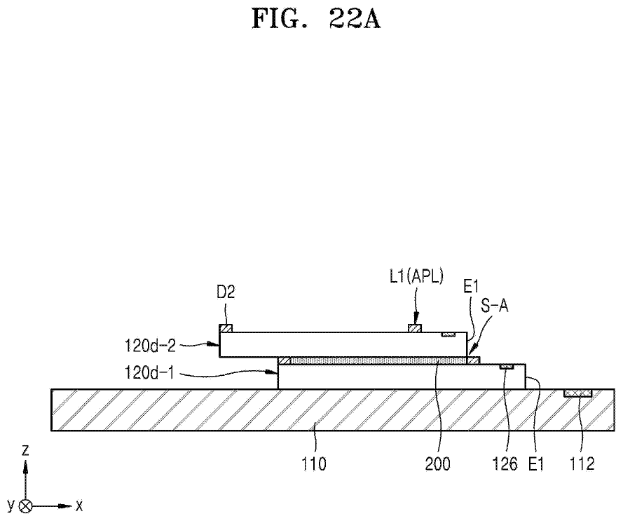

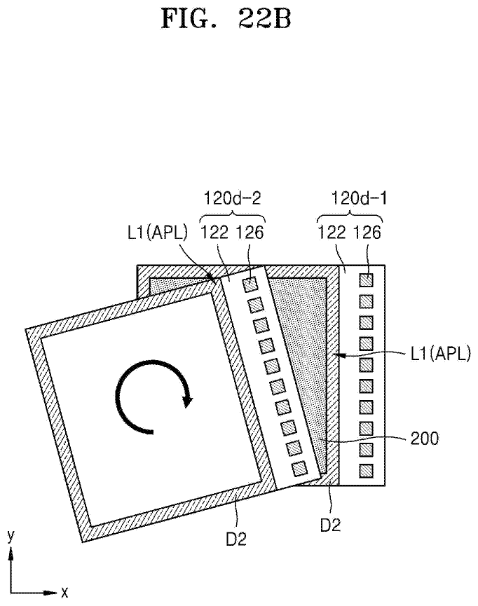

In FIGS. 22A and 22B, after the hydrophilic liquid 200 is applied, a second semiconductor chip 120d-2 is stacked on the first semiconductor chip 120d-1. As described above, the lower surface of the second semiconductor chip 120d-2 may be hydrophilic. Accordingly, when stacking the second semiconductor chip 120d-2, the lower surface of the second semiconductor chip 120d-2 may be wetted by and coupled to the hydrophilic liquid 200 on the first semiconductor chip 120d-1. Also, as indicated by a circular arrow in FIG. 22B, due to the surface tension of the hydrophilic liquid 200, the second semiconductor chip 120d-2 may be automatically self-aligned with the first semiconductor chip 120d-1 through rotational movement and/or straight-line movement. For example, a first edge E1 of the second semiconductor chip 120d-2 may be self-aligned with the alignment pattern line APL, that is, the first line L1 of the second dam D2 of the first semiconductor chip 120d-1.

Subsequently, a third semiconductor chip 120d-3 and a fourth semiconductor chip 120d-4 are stacked, and the chip stack structure 120d of FIG. 5A may be formed through a bake process. Also, a wire 130, a sealing material 140, and an external connection terminal 150 may be formed, thereby completing the semiconductor package 100c of FIG. 5A.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A semiconductor package comprising:
a package substrate; and
at least two semiconductor chips stacked on the package substrate and electrically connected to the package substrate via a wire,
wherein a first semiconductor chip located on a lower side among the at least two semiconductor chips is coupled, without an adhesive, to a second semiconductor chip located above the first semiconductor chip.

2. The semiconductor package of claim 1, wherein:
each of the at least two semiconductor chips has an upper surface and a lower surface having rectangular shapes, and the upper surface comprises an active surface and the lower surface comprises a non-active surface,
chip pads are arranged in a first direction on the upper surface of each of the at least two semiconductor chips, the chip pads are adjacent to a first edge that corresponds to one line of the rectangular shapes of the upper and lower surfaces of each of the at least two semiconductor chips and extend in the first direction,
an alignment pattern line is formed on the upper surface of the first semiconductor chip and extends parallel to the first edge of the upper surface of the first semiconductor chip, and
the first edge of the lower surface of the second semiconductor chip is self-aligned with the alignment pattern line of the first semiconductor chip.

3. The semiconductor package of claim 2, wherein the alignment pattern line comprises a trench or dam formed in the first semiconductor chip.

4. The semiconductor package of claim 2, wherein the alignment pattern line comprises one of:
a first trench having a line shape and formed in a protective layer on the upper surface of the first semiconductor chip,
a first line of a second trench having a quadrangular ring shape and formed in the protective layer, wherein the first line of the second trench is adjacent to the first edge of the upper surface of the first semiconductor chip,
a first dam having a line shape and formed on the upper surface of the first semiconductor chip, and
a first line of a second dam having a quadrangular ring shape and formed on the upper surface of the first semiconductor chip, wherein the first line of the second dam is adjacent to the first edge of the upper surface of the first semiconductor chip.

5. The semiconductor package of claim 4, wherein:
the alignment pattern line is formed by the first line of the second trench, and
three lines, other than the first line of the second trench, are spaced a certain distance from three edges, other than the first edge of the upper surface of the first semiconductor chip, or from expose regions of the upper surface of the first semiconductor chip adjacent to the three edges of the first semiconductor chip.

6. The semiconductor package of claim 4,
wherein the alignment pattern line is formed by the first line of the second dam, and
wherein a gap exists between the first semiconductor chip and the second semiconductor chip and is adjacent to three lines other than the first line of the second dam.

7. The semiconductor package of claim 1, wherein a semiconductor chip that is lowermost among the at least two semiconductor chips is bonded to the package substrate without an adhesive.

8. The semiconductor package of claim 7,
wherein the lowermost semiconductor chip is disposed on a solder resist (SR) open region of the package substrate, and
wherein the SR open region is formed by removing a portion of an SR layer on an upper surface of the package substrate.

9. The semiconductor package of claim 1, wherein the semiconductor package has one of:
a thickness less than that of a first semiconductor package comprising an adhesive by a thickness of the adhesive, and
a thickness that is substantially the same thickness as the first semiconductor package, with each of the at least two semiconductor chips being thicker than a semiconductor chip of the first semiconductor package.

10. The semiconductor package of claim 1, wherein a semiconductor chip that is lowermost among the at least two semiconductor chips is bonded to the package substrate with an adhesive.

11. The semiconductor package of claim 1, wherein the at least two semiconductor chips are stacked in a step shape or zigzag shape on the package substrate.

12. A semiconductor package comprising:
a package substrate having a solder resist (SR) layer formed on an upper surface thereof;
a first semiconductor chip coupled to the package substrate without an adhesive, the first semiconductor chip being electrically connected to the package substrate via a first wire; and
at least two second semiconductor chips coupled to the first semiconductor chip without an adhesive, the at least two second semiconductor chips being electrically connected to the package substrate via a second wire,
wherein a lower second semiconductor chip, among the at least two second semiconductor chips, located on a lower side is coupled, without an adhesive, to an upper second semiconductor chip located above the lower second semiconductor chip,
wherein the lower second semiconductor chip that is lowermost among the at least two second semiconductor chips is self-aligned with a first alignment pattern line on an upper surface of the first semiconductor chip, and
wherein the upper second semiconductor chip is self-aligned with a second alignment pattern line on an upper surface of the lower second semiconductor chip.

13. The semiconductor package of claim 12,
wherein each of the first semiconductor chip and the at least two second semiconductor chips has an upper surface and a lower surface having rectangular shapes, and the upper surface comprises an active surface and the lower surface comprises a non-active surface,
wherein the first alignment pattern line and the second alignment pattern line are adjacent to first edges that correspond to one line of the rectangular shapes of the upper and lower surfaces of the first semiconductor chip and the at least two second semiconductor chips and extend in the first direction, and the first alignment pattern line and the second alignment pattern line extend parallel to the first edges on the upper surfaces of the first semiconductor chip and the at least two second semiconductor chips,
wherein the first edge of the lower second semiconductor chip that is the lowermost among the at least two second semiconductor chips is self-aligned with the first alignment pattern line of the first semiconductor chip, and
wherein the first edge of the upper second semiconductor chip is self-aligned with the second alignment pattern line of the lower second semiconductor chip.

14. The semiconductor package of claim 13, wherein the first alignment pattern line or the second alignment pattern line comprises one of:
a first trench having a line shape and formed in a protective layer on the upper surface of the first semiconductor chip or the lower second semiconductor chip,
a first line of a second trench having a quadrangular ring shape and formed in the protective layer, wherein the first line of the second trench is adjacent to the first edge of the upper surface of the first semiconductor chip or the lower second semiconductor chip,
a first dam having a line shape and formed on the upper surface of the first semiconductor chip or the lower second semiconductor chip, and
a first line of a second dam having a quadrangular ring shape and formed on the upper surface of the first semiconductor chip or the lower second semiconductor chip, wherein the first line of the second dam is adjacent to the first edge of the upper surface of the first semiconductor chip or the lower second semiconductor chip.

15. The semiconductor package of claim 12, wherein the first semiconductor chip is disposed on an SR open region formed by removing a portion of the SR layer.

16. The semiconductor package of claim 12, wherein the semiconductor package has one of:
a thickness less than that of a first semiconductor package comprising an adhesive by a thickness of the adhesive, and
a thickness that is substantially the same thickness as the first semiconductor package, with each of the first semiconductor chip and at least two second semiconductor chips being thicker than a semiconductor chip of the first semiconductor package.

17. A semiconductor package comprising:
a package substrate; and
at least two semiconductor chips stacked on the package substrate and each having an upper surface and a lower surface having rectangular shapes,
wherein the upper surface of each of the at least two semiconductor chips comprises an active surface and the lower surface of each of the at least two semiconductor chips comprises a non-active surface, and chip pads are arranged in a first direction on the upper surface of each of the at least two semiconductor chips, the chip pads are adjacent to a first edge that corresponds to one line of the rectangular shapes of the upper and lower surfaces of each of the at least two semiconductor chips and extend in the first direction,
wherein the at least two semiconductor chips are stacked on each other such that the chip pads thereof are exposed to the outside, and the chip pads are electrically connected to substrate pads of the package substrate via wires, and
wherein a first semiconductor chip located on a lower side among the at least two semiconductor chips is coupled, without an adhesive, to a second semiconductor chip located above the first semiconductor chip.

18. The semiconductor package of claim 17, further comprising an alignment pattern line formed on the upper surface of the first semiconductor chip, the alignment pattern line extends parallel to the first edge of the upper surface of the first semiconductor chip,
wherein the first edge of the lower surface of the second semiconductor chip is self-aligned with the alignment pattern line of the first semiconductor chip.

19. The semiconductor package of claim 18, wherein the alignment pattern line comprises one of:
a first trench having a line shape and formed in a protective layer on the upper surface of the first semiconductor chip,
a first line of a second trench having a quadrangular ring shape and formed in the protective layer, wherein the first line of the second trench is adjacent to the first edge of the upper surface of the first semiconductor chip,
a first dam having a line shape and formed on the upper surface of the first semiconductor chip, and
a first line of a second dam having a quadrangular ring shape and formed on the upper surface of the first semiconductor chip, wherein the first line of the second dam is adjacent to the first edge of the upper surface of the first semiconductor chip.

20. The semiconductor package of claim 17, wherein a semiconductor chip that is lowermost among the at least two semiconductor chips is bonded to the package substrate without an adhesive.

21.-25. (canceled)
